(19) United States
(12) Patent Application Publication
(10) Pub. No.: US 2023/0072989 A1
(43) Pub. Date: Mar. 9, 2023

(54) SEMICONDUCTOR DEVICE

(71) Applicant: ROHM CO., LTD., Kyoto-shi, Kyoto (JP)

(72) Inventor: Masaki NAGATA, Kyoto-shi, Kyoto (JP)

(73) Assignee: ROHM CO., LTD., Kyoto-shi, Kyoto (JP)

(21) Appl. No.: 17/795,872

(22) PCT Filed: Feb. 1, 2021
(86) PCT No.: PCT/JP2021/003557

§ 371 Date: Jul. 28, 2022

(30) Foreign Application Priority Data
Feb. 7, 2020 (JP) 2020-020082

(51) Int. Cl. H01L 29/78; H01L 29/66

(52) U.S. Cl. CPC H01L 29/7845; H01L 29/66727; H01L 29/66734; H01L 29/7813; H01L 29/66545

(57) ABSTRACT

A semiconductor device includes a semiconductor chip which has a main surface, a first groove which is formed in the main surface and demarcates the main surface into a first region and a second region, a first insulating film which is formed on a wall surface of the first groove, a second groove which is formed in the main surface of the first region at an interval from the first groove, a second insulating film which covers an upper wall surface of the second groove and is thinner than the first insulating film, a third insulating film which covers a lower wall surface of the second groove and is thicker than the second insulating film, a third groove which is formed in the main surface of the second region at an interval from the first groove, a fourth insulating film, and a fifth insulating film.

### TECHNICAL FIELD

This application corresponds to Japanese Patent Application No. 2020-020082 filed with the Japan Patent Office on Feb. 7, 2020, and the entire disclosure of this application is incorporated herein by reference.

The present invention relates to a semiconductor device.

### BACKGROUND ART

Patent Literature 1 discloses a semiconductor device which includes a semiconductor chip, a first groove structure, and a second groove structure. The first groove structure includes a first groove and a first insulating film. The first groove is formed in a main surface of the semiconductor chip and demarcates the main surface into an active region and a non-active region. The first insulating film is formed on a wall surface of the first groove. The second groove structure includes a second groove, a second insulating film, and a third insulating film. The second groove is formed in a main surface of the active region at an interval from the first groove. The second insulating film covers an upper wall surface of the second groove and is formed thinner than the first insulating film. The third insulating film covers a lower wall surface of the second groove and is formed thicker than the second insulating film.

### CITATION LIST

### Patent Literature

Patent Literature 1: Japanese Translation of International Application No. 2013-508980

### SUMMARY OF INVENTION

### Technical Problem

Where a structure inside the first groove is different from a structure inside the second groove, a stress may occur in a region of the semiconductor chip between the first groove and the second groove, thereby a crystal defect may be formed. One embodiment of the present invention provides a semiconductor device capable of suppressing a crystal defect of a semiconductor chip.

### Solution to Problem

One embodiment of the present invention provides a semiconductor device which includes a semiconductor chip that has a main surface, a first groove which is formed in the main surface and demarcates the main surface into a first region and a second region, a first insulating film which is formed on a wall surface of the first groove, a second groove which is formed in the main surface of the first region at an interval from the first groove, a second insulating film which covers an upper wall surface of the second groove and is thinner than the first insulating film, a third insulating film which covers a lower wall surface of the second groove and is thicker than the second insulating film, a third groove which is formed in the main surface of the second region at an interval from first groove, a fourth insulating film which covers an upper wall surface of the third groove and is thinner than the first insulating film, and a fifth insulating film which covers a lower wall surface of the third groove and is thicker than the fourth insulating film.

One embodiment of the present invention provides a semiconductor device which includes a semiconductor chip that has a main surface, a field trench structure which is formed in the main surface and demarcates an active region and a non-active region in the main surface, a trench gate structure which is formed in the active region at an interval from the trench separating structure and faces the field trench structure, and a dummy trench structure which is formed in the non-active region at an interval from the trench separating structure and faces the trench gate structure across the field trench structure.

The aforementioned as well as yet other objects, features and effects of the present invention will be made clear by the following description of the embodiments with reference to the accompanying drawings.

### BRIEF DESCRIPTION OF DRAWINGS

FIG. 1 is a plan view showing a semiconductor device according to a first embodiment of the present invention.

FIG. 2 is a plan view showing a structure of a first main surface of a semiconductor chip shown in FIG. 1.

FIG. 3 is an enlarged view of a region III shown in FIG. 2.

FIG. 4 is a cross-sectional view along line IV-IV shown in FIG. 3.

FIG. 5 is a cross-sectional view along line V-V shown in FIG. 3.

FIG. 6 is a cross-sectional view along line VI-VI shown in FIG. 3.

FIG. 7 is an enlarged view of a region VII shown in FIG. 2.

FIG. 8A is a cross-sectional view for describing one example of a method for manufacturing the semiconductor device shown in FIG. 1.

FIG. 8B is a cross-sectional view showing a step subsequent to that of FIG. 8A.

FIG. 8C is a cross-sectional view showing a step subsequent to that of FIG. 8B.

FIG. 8D is a cross-sectional view showing a step subsequent to that of FIG. 8C.

FIG. 8E is a cross-sectional view showing a step subsequent to that of FIG. 8D.

FIG. 8F is a cross-sectional view showing a step subsequent to that of FIG. 8E.

FIG. 8G is a cross-sectional view showing a step subsequent to that of FIG. 8F.

FIG. 8H is a cross-sectional view showing a step subsequent to that of FIG. 8G.

FIG. 8I is a cross-sectional view showing a step subsequent to that of FIG. 8H.

FIG. 8J is a cross-sectional view showing a step subsequent to that of FIG. 8I.

FIG. 8K is a cross-sectional view showing a step subsequent to that of FIG. 8J.

FIG. 8L is a cross-sectional view showing a step subsequent to that of FIG. 8K.

FIG. 8M is a cross-sectional view which is a step subsequent to that of FIG. 8L.

FIG. 8N is a cross-sectional view showing a step subsequent to that of FIG. 8M.

FIG. 8O is a cross-sectional view showing a step subsequent to that of FIG. 8N.

FIG. 8P is a cross-sectional view showing a step subsequent to that of FIG. 8O.

FIG. 8Q is a cross-sectional view showing a step subsequent to that of FIG. 8P.

FIG. 8R is a cross-sectional view showing a step subsequent to that of FIG. 8Q.

FIG. 8S is a cross-sectional view showing a step subsequent to that of FIG. 8R.

FIG. 8T is a cross-sectional view showing a step subsequent to that of FIG. 8S.

FIG. 9 is a drawing corresponding to FIG. 4 and a cross-sectional view for describing a stress where no dummy trench gate structure is present.

FIG. 10 is a drawing corresponding to FIG. 4 and a cross-sectional view for describing a stress where the dummy trench gate structure is present.

FIG. 11 is a drawing corresponding to FIG. 2 and a plan view showing a structure of a first main surface of a semiconductor chip of a semiconductor device according to a second embodiment of the present invention.

FIG. 12 is an enlarged view of a region XII shown in FIG. 11.

FIG. 13 is a cross-sectional view along line XIII-XIII shown in FIG. 12.

FIG. 14 is a cross-sectional view along line XIV-XIV shown in FIG. 12.

FIG. 15 is a cross-sectional view along line XV-XV shown in FIG. 12.

FIG. 16 is an enlarged view of a region XVI shown in FIG. 11.

FIG. 17A is a cross-sectional view for describing one example of a method for manufacturing the semiconductor device shown in FIG. 11.

FIG. 17B is a cross-sectional view showing a step subsequent to that of FIG. 17A.

FIG. 17C is a cross-sectional view showing a step subsequent to that of FIG. 17B.

FIG. 17D is a cross-sectional view showing a step subsequent to that of FIG. 17C.

FIG. 17E is a cross-sectional view showing a step subsequent to that of FIG. 17D.

FIG. 17F is a cross-sectional view showing a step subsequent to that of FIG. 17E.

FIG. 17G is a cross-sectional view showing a step subsequent to that of FIG. 17F.

FIG. 17H is a cross-sectional view showing a step subsequent to that of FIG. 17G.

FIG. 17I is a cross-sectional view showing a step subsequent to that of FIG. 17H.

FIG. 17J is a cross-sectional view showing a step subsequent to that of FIG. 17I.

FIG. 17K is a cross-sectional view showing a step subsequent to that of FIG. 17J.

FIG. 17L is a cross-sectional view showing a step subsequent to that of FIG. 17K.

FIG. 17M is a cross-sectional view showing a step subsequent to that of FIG. 17L.

FIG. 17N is a cross-sectional view showing a step subsequent to that of FIG. 17M.

FIG. 17O is a cross-sectional view showing a step subsequent to that of FIG. 17N.

FIG. 17P is a cross-sectional view showing a step subsequent to that of FIG. 17O.

FIG. 17Q is a cross-sectional view showing a step subsequent to that of FIG. 17P.

FIG. 17R is a cross-sectional view showing a step subsequent to that of FIG. 17Q.

FIG. 17S is a cross-sectional view showing a step subsequent to that of FIG. 17R.

FIG. 17T is a cross-sectional view showing a step subsequent to that of FIG. 17S.

FIG. 18 is a drawing corresponding to FIG. 12 and an enlarged view showing a structure of a first main surface of a semiconductor chip of a semiconductor device according to a third embodiment of the present invention.

FIG. 19 is a cross-sectional view along line XIX-XIX shown in FIG. 18.

FIG. 20 is a cross-sectional view along line XX-XX shown in FIG. 18.

### DESCRIPTION OF EMBODIMENTS

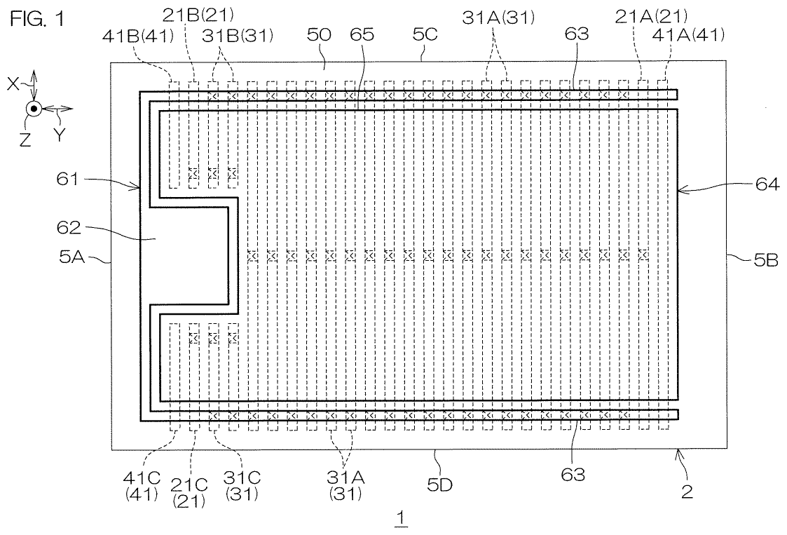

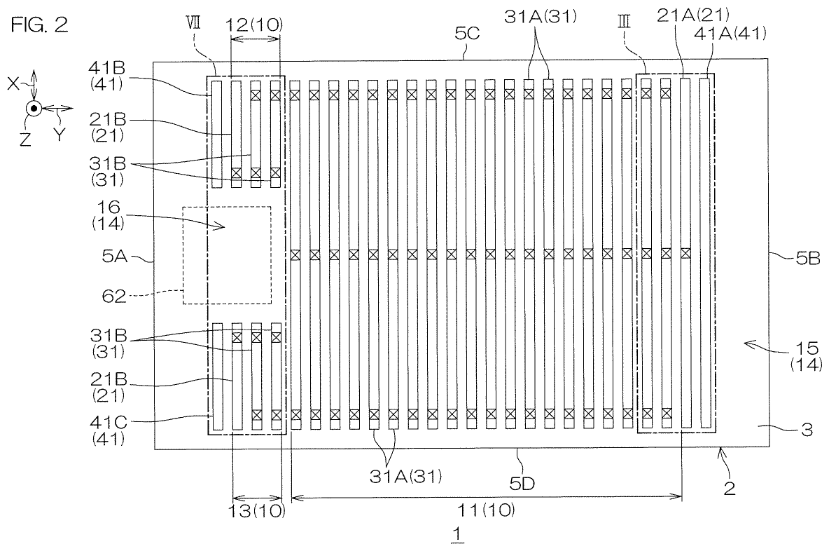

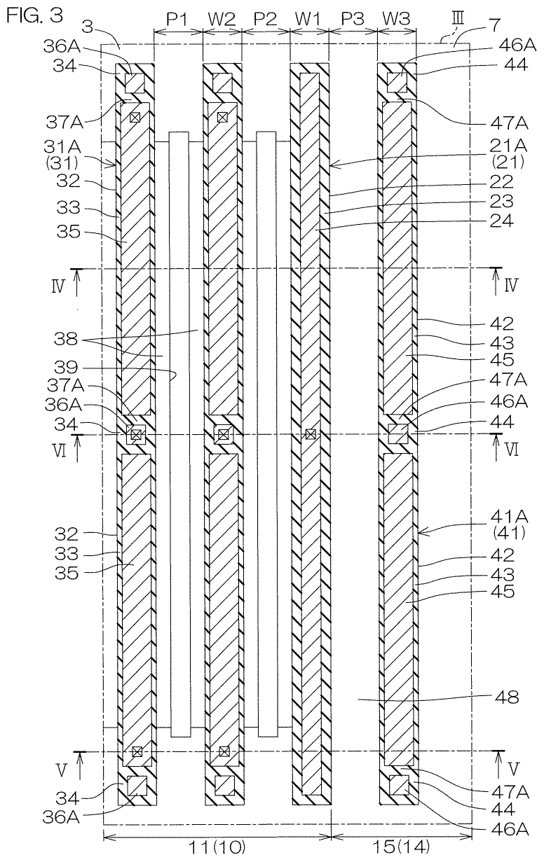

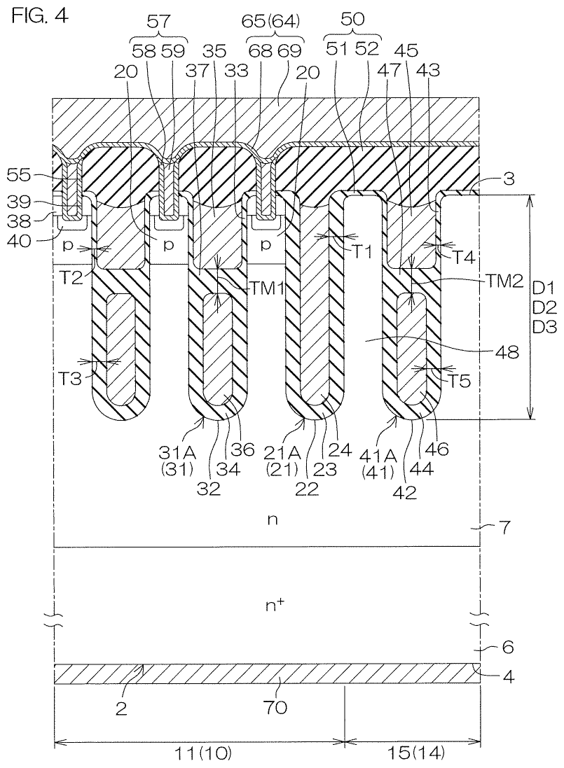

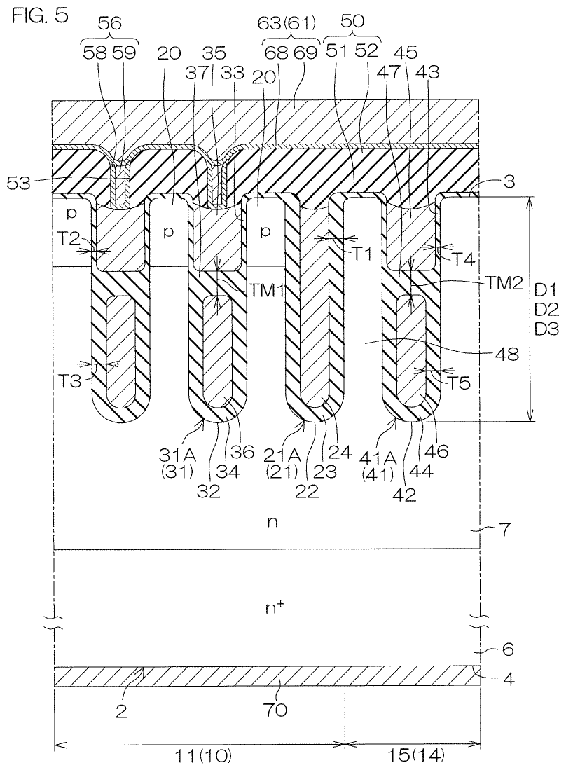

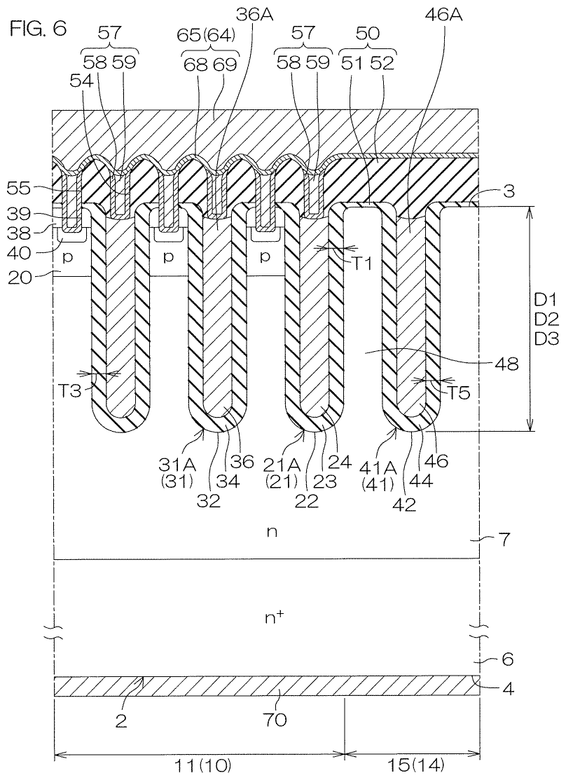

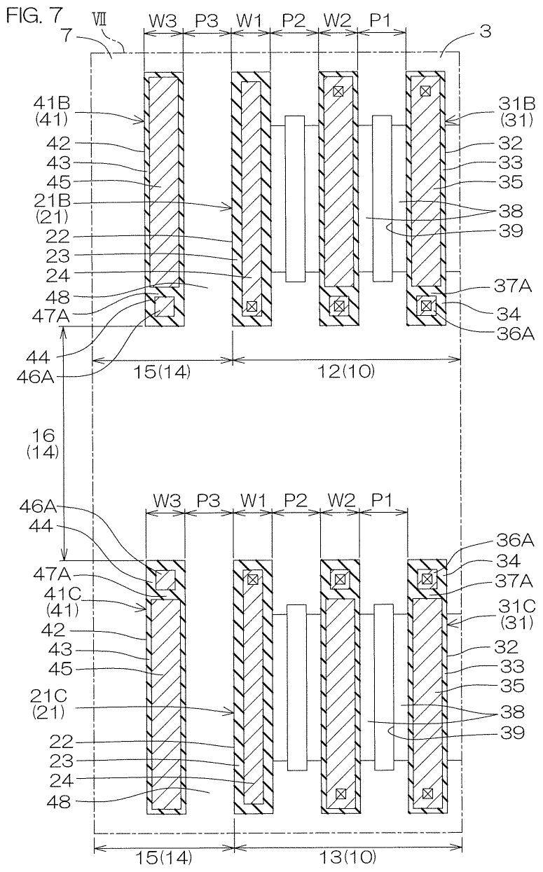

FIG. 1 is a plan view showing a semiconductor device 1 according to the first embodiment of the present invention. FIG. 2 is a plan view showing a structure of a first main surface 3 of a semiconductor chip 2 shown in FIG. 1. FIG. 3 is an enlarged view of a region III shown in FIG. 2. FIG. 4 is a cross-sectional view along line IV-IV shown in FIG. 3. FIG. 5 is a cross-sectional view along line V-V shown in FIG. 3. FIG. 6 is a cross-sectional view along line VI-VI shown in FIG. 3. FIG. 7 is an enlarged view of a region VII shown in FIG. 2.

With reference to FIG. 1 to FIG. 7, the semiconductor device 1 includes the semiconductor chip 2 which is made of silicon and formed in a rectangular parallelepiped shape. The semiconductor chip 2 includes a first main surface 3 on one side, a second main surface 4 on the other side, and side surfaces 5A, 5B, 5C, 5D which connect the first main surface 3 and the second main surface 4. The first main surface 3 and the second main surface 4 are each formed in a quadrilateral shape (specifically, in a rectangular shape) in a plan view as viewed in a normal direction Z thereto (hereinafter, referred to simply as “in a plan view”).

The side surfaces 5A to 5D include a first side surface 5A, a second side surface 5B, a third side surface 5C, and a fourth side surface 5D. The first side surface 5A and the second side surface 5B extend in a first direction X and face each other in a second direction Y which intersects the first direction X. Specifically, the second direction Y is orthogonal to the first direction X. The first side surface 5A and the second side surface 5B each form a short side of the semiconductor chip 2. The third side surface 5C and the fourth side surface 5D extend in the second direction Y and face each other in the first direction X. The third side surface 5C and the fourth side surface 5D each form a long side of the semiconductor chip 2.

The semiconductor chip 2 includes an n⁺-type drain region 6 and an n-type drift region 7. The drain region 6 is formed in a surface layer portion of the second main surface 4. The drain region 6 is preferably formed across an entire area of the surface layer portion of the second main surface 4. An n-type impurity concentration of the drain region 6 may be not less than 1×10¹⁸ cm⁻³ and not more than 1×10²¹ cm⁻³. In this embodiment, the drain region 6 is formed of a semiconductor substrate.

The thickness of the drain region 6 may be not less than 50 μm and not more than 400 μm. The thickness of the drain region 6 may be not less than 50 μm and not more than 100 μm, not less than 100 μm and not more than 200 μm, not less than 200 μm and not more than 300 μm, or not less than 300 μm and not more than 400 μm. The thickness of the drain region 6 is preferably not less than 50 μm and not more than 150 μm.

The drift region 7 is formed in a surface layer portion of the first main surface 3. The drift region 7 is preferably formed across an entire area of the surface layer portion of the first main surface 3. The drift region 7 is formed in a region between the first main surface 3 and the drain region 6 and electrically connected to the drain region 6. The drift region 7 has an n-type impurity concentration which is less than the n-type impurity concentration of the drain region 6. The n-type impurity concentration drift of the region 7 may be not less than 1×10¹⁵ cm⁻³ and not more than 1×10¹⁸ cm⁻³. In this embodiment, the drift region 7 is formed of an epitaxial layer.

The drift region 7 has a thickness which is less than the thickness of the drain region 6. The thickness of the drift region 7 may be not less than 2 μm and not more than 30 μm. The thickness of the drift region 7 may be not less than 2 μm and not more than 5 μm, not less than 5 μm and not more than 10 μm, not less than 10 μm and not more than 15 μm, not less than 15 μm and not more than 20 μm, not less than 20 μm and not more than 25 μm, or not less than 25 μm and not more than 30 μm. The thickness of the drift region 7 is preferably not less than 5 μm and not more than 15 μm.

With reference to FIG. 2, the semiconductor device 1 includes an active region 10 (first region) which is formed in the first main surface 3 at an interval inward from the side surfaces 5A to 5D. The active region 10 is a region where a MISFET (Metal Insulator Semiconductor Field Effect Transistor) is formed as a functional device. Specifically, the active region 10 includes a first active region 11, a second active region 12, and a third active region 13. The first active region 11 is formed in a central portion of the first main surface 3. The first active region 11 is formed in a quadrilateral shape (rectangular shape extending in the second direction Y) in a plan view.

The second active region 12 is formed in a region between the first side surface 5A and the first active region 11. When a center line which traverses the central portion of the first main surface 3 in the second direction Y is set, the second active region 12 is formed at an interval from the center line to one side of the first direction X (the third side surface 5C side). The second active region 12 is formed in a quadrilateral shape (rectangular shape extending in the first direction X) in a plan view. The second active region 12 faces the first active region 11 in the second direction Y.

The third active region 13 is formed in a region between the first side surface 5A and the first active region 11. When a center line which traverses the central portion of the first main surface 3 in the second direction Y is set, the third active region 13 is formed at an interval from the center line to the other side of the first direction X (the fourth side surface 5D side). The third active region 13 is formed in a quadrilateral shape (rectangular shape extending in the first direction X) in a plan view. The third active region 13 faces the first active region 11 in the second direction Y and faces the second active region 12 in the first direction X.

The semiconductor device 1 includes a non-active region 14 (second region) which is formed in the first main surface 3. The non-active region 14 is formed outside the active region 10 and is a region in which no functional device (MISFET) is formed. Specifically, the non-active region 14 includes an outer peripheral region 15 and a pad region 16. The outer peripheral region 15 is formed annularly such as to surround the active region 10 in a plan view. Specifically, the outer peripheral region 15 extends in a band shape along the side surfaces 5A to 5D in a plan view and collectively surrounds the first active region 11, the second active region 12, and the third active region 13. The pad region 16 is formed in a quadrilateral shape in a region between the second active region 12 and the third active region 13 in a plan view.

With reference to FIG. 3 to FIG. 6, the semiconductor device 1 includes a p-type body region 20 which is formed in the surface layer portion of the first main surface 3 in the active region 10. The body region 20 is uniformly formed across an entire area of the active region 10. The body region 20 is formed at an interval from a bottom portion of the drift region 7 to the first main surface 3 side. A p-type impurity concentration of the body region 20 may be not less than 1×10¹⁶ cm⁻³ and not more than 1×10¹⁸ cm⁻³.

With reference to FIG. 2 to FIG. 7, the semiconductor device 1 includes a plurality of (three in this embodiment) field trench structures 21 (first groove structures) formed in the first main surface 3. In this embodiment, the plurality of field trench structures 21 include one first field trench structure 21A, one second field trench structure 21B, and one third field trench structure 21C.

The first field trench structure 21A is formed in a region of the first main surface 3 on the second side surface 5B side at an interval from the second side surface 5B to the first side surface 5A side. The first field trench structure 21A is formed in a band shape extending in the first direction X in a plan view. The first field trench structure 21A demarcates the first active region 11 in a region of the first main surface 3 on one side (the first side surface 5A side) and demarcates the non-active region 14 in a region of the first main surface 3 on the other side (the second side surface 5B side).

When a line which traverses the pad region 16 in the second direction Y is set, the first field trench structure 21A traverses the line in the first direction X. Thereby, the first field trench structure 21A faces the pad region 16 across the first active region 11.

The first field trench structure 21A has a single electrode structure which includes a first trench 22 (first groove), a first insulating film 23, and a first electrode 24. The first trench 22, the first insulating film 23, and the first electrode 24 may be respectively referred to as a “field trench,” a “field insulating film,” and a “field electrode.” The first trench 22 is formed by digging down the first main surface 3 toward the second main surface 4. The first trench 22 penetrates through the body region 20 and is formed at an interval from the bottom portion of the drift region 7 to the first main surface 3 side.

An angle which is formed between a side wall of the first trench 22 and the first main surface 3 inside the semiconductor chip 2 may be not less than 90° and not more than 92°. The first trench 22 may be formed in a tapered shape in which an opening width is narrowed from an opening thereof to a bottom wall thereof. The bottom wall of the first trench 22 is preferably formed in a curved shape toward the second main surface 4.

The first trench 22 has a first width W1. The first width W1 is a width in a direction orthogonal to a direction in which the first trench 22 extends (that is, in the second direction Y). The first width W1 may be not less than 0.5 μm and not more than 3 μm. The first width W1 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The first width W1 is preferably not less than 0.5 μm and not more than 2 μm.

The first trench 22 has a first depth D1. The first depth D1 may be not less than 1 μm and not more than 10 μm. The first depth D1 may be not less than 1 μm and not more than 2 μm, not less than 2 μm and not more than 4 μm, not less than 4 μm and not more than 6 μm, not less than 6 μm and not more than 8 μm, or not less than 8 μm and not more than 10 μm. The first depth D1 is preferably not less than 1 μm and not more than 5 μm.

The first trench 22 has a first aspect ratio, D1/W1. The first aspect ratio, D1/W1, is a ratio of the first depth D1 in relation to the first width W1. The first aspect ratio, D1/W1, is preferably in excess of 1 and not more than 5. The first aspect ratio, D1/W1, is in particular preferably not less than 3 and not more than 5.

The first insulating film 23 is formed along a wall surface of the first trench 22. Specifically, the first insulating film 23 is formed as a film across an entire area of the wall surface of the first trench 22 and demarcates a U-shaped recess space inside the first trench 22. In this embodiment, the first insulating film 23 contains a silicon oxide.

The first insulating film 23 has a first thickness T1. The first thickness T1 is a thickness of the first insulating film 23 along a normal direction of the wall surface of the first trench 22. The first thickness T1 may be not less than 0.1 μm and not more than 1 μm. The first thickness T1 may be not less than 0.1 μm and not more than 0.25 μm, not less than 0.25 μm and not more than 0.5 μm, not less than 0.5 μm and not more than 0.75 μm, or not less than 0.75 μm and not more than 1 μm. The first thickness T1 is preferably not less than 0.15 μm and not more than 0.65 μm.

The first electrode 24 is embedded in the first trench 22 across the first insulating film 23. The first electrode 24 traverses a depth position of a bottom portion of the body region 20 and faces the body region 20 and the drift region 7 across the first insulating film 23. That is, the first electrode 24 includes a portion which is positioned on the first main surface 3 side with respect to the bottom portion of the body region 20 and a portion which is positioned on the bottom wall side of the first trench 22 with respect to the bottom portion of the body region 20. In this embodiment, the first electrode 24 contains a conductive polysilicon. The first electrode 24 is formed as a field electrode. A source potential (for example, a ground potential) as a reference potential is to be applied to the first electrode 24.

The second field trench structure 21B is formed at an interval from the pad region 16 to one side (the third side surface 5C side) in terms of the first direction X. The second field trench structure 21B is formed in a region of the first main surface 3 on the first side surface 5A side at an interval from the first side surface 5A to the second side surface 5B side. The second field trench structure 21B is formed in a band shape extending in the first direction X in a plan view.

The second field trench structure 21B demarcates the second active region 12 in a region of the first main surface 3 on the other side (the second side surface 5B side) and demarcates the non-active region 14 in a region of the first main surface 3 on one side (the first side surface 5A side). The second field trench structure 21B faces the first field trench structure 21A across the first active region 11 and the second active region 12.

As with the first field trench structure 21A, the second field trench structure 21B has a single electrode structure which includes a first trench 22, a first insulating film 23, and a first electrode 24. The second field trench structure 21B has the same structure as the first field trench structure 21A except for a difference in length of the first trench 22. A specific description of the second field trench structure 21B will be omitted.

The third field trench structure 21C is formed at an interval from the pad region 16 to the other side (the fourth side surface 5D side) in terms of the first direction X. The third field trench structure 21C is formed in a region of the first main surface 3 on the first side surface 5A side at an interval from the first side surface 5A to the second side surface 5B side. The third field trench structure 21C is formed in a band shape extending in the first direction X in a plan view.

The third field trench structure 21C demarcates the third active region 13 in a region of the first main surface 3 on the other side (the second side surface 5B side) and demarcates the non-active region 14 in a region of the first main surface 3 on one side (the first side surface 5A side). The third field trench structure 21C faces the first field trench structure 21A across the first active region 11 and the third active region 13 and faces the second field trench structure 21B across the pad region 16.

As with the first field trench structure 21A, the third field trench structure 21C has a single electrode structure which includes a first trench 22, a first insulating film 23, and a first electrode 24. The third field trench structure 21C has the same structure as the first field trench structure 21A except for a difference in length of the first trench 22. A specific description of the third field trench structure 21C will be omitted.

With reference to FIG. 2 to FIG. 7, the semiconductor device 1 includes a plurality of trench gate structures 31 (second groove structures) which are formed in the first main surface 3 in the active region 10. In this embodiment, the plurality of trench gate structures 31 include a plurality of first trench gate structures 31A, a plurality of second trench gate structures 31B and a plurality of third trench gate structures 31C.

The plurality of first trench gate structures 31A are formed in the first active region 11. The plurality of first trench gate structures 31A are formed at an interval from the pad region 16 and the first field trench structure 21A. The plurality of first trench gate structures 31A are each formed in a band shape extending in the first direction X in a plan view and formed, with an interval kept in the second direction Y. The plurality of first trench gate structures 31A are formed in a striped shape extending in the first direction X. That is, the plurality of first trench gate structures 31A extend in parallel with the first field trench structure 21A in a plan view.

The plurality of first trench gate structures 31A are formed, with a first interval P1 kept from each other. The first interval P1 may be not less than 0.1 μm and not more than 2 μm. The first interval P1 may be not less than 0.1 μm and not more than 0.5 μm, not less than 0.5 μm and not more than 1 μm, not less than 1 μm and not more than 1.5 μm, or not less than 1.5 μm and not more than 2 μm. The first interval P1 is preferably not less than 0.5 μm and not more than 1.5 μm.

The first trench gate structure 31A is formed, with a second interval P2 kept from the first field trench structure 21A. The second interval P2 may be not less than 0.1 μm and not more than 2 μm. The second interval P2 may be not less than 0.1 μm and not more than 0.5 μm, not less than 0.5 μm and not more than 1 μm, not less than 1 μm and not more than 1.5 μm, or not less than 1.5 μm and not more than 2 μm. The second interval P2 is preferably not less than 0.5 μm and not more than 1.5 μm. The second interval P2 is preferably equal to the first interval P1. The second interval P2 being equal to the first interval P1 means that a value of the second interval P2 is within a range of ±10%, with a value of the first interval P1 given as a reference.

The plurality of first trench gate structures 31A each have a split electrode structure (multi-electrode structure) which includes a second trench 32 (second groove), a second insulating film 33, a third insulating film 34, a second electrode 35, a third electrode 36, and a first intermediate insulating film 37. The second trench 32, the second insulating film 33, the third insulating film 34, the second electrode 35, and the third electrode 36 may be respectively referred to as a “gate trench,” an “upper insulating film,” a “lower insulating film,” an “upper electrode,” and a “lower electrode.” The second trench 32 is formed by digging down the first main surface 3 toward the second main surface 4. The second trench 32 penetrates through the body region 20 and is formed at an interval from the bottom portion of the drift region 7 to the first main surface 3 side.

An angle which is formed between a side wall of the second trench 32 and the first main surface 3 inside the semiconductor chip 2 may be not less than 90° and not more than 92°. The second trench 32 may be formed in a tapered shape in which an opening width is narrowed from an opening thereof toward a bottom wall thereof. The bottom wall of the second trench 32 is preferably formed in a curved shape toward the second main surface 4.

The second trench 32 has a second width W2. The second width W2 is a width in a direction orthogonal to a direction in which the second trench 32 extends (that is, in the second direction Y). The second width W2 may be not less than 0.5 μm and not more than 3 μm. The second width W2 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The second width W2 is preferably not less than 0.5 μm and not more than 2 μm.

The second trench 32 has a second depth D2. The second depth D2 may be not less than 1 μm and not more than 10 μm. The second depth D2 may be not less than 1 μm and not more than 2 μm, not less than 2 μm and not more than 4 μm, not less than 4 μm and not more than 6 μm, not less than 6 μm and not more than 8 μm, or not less than 8 μm and not more than 10 μm. The second depth D2 is preferably not less than 1 μm and not more than 5 μm.

The second width W2 is preferably equal to the first width W1 of the first trench 22. The second width W2 being equal to the first width W1 means that a value of the second width W2 is within a range of ±10%, with a value of the first width W1 given as a reference. The second depth D2 is preferably equal to the first depth D1 of the first trench 22. The second depth D2 being equal to the first depth D1 means that a value of the second depth D2 is within a range of ±10%, with a value of the first depth D1 given as a reference.

The second trench 32 has a second aspect ratio, D2/W2. The second aspect ratio, D2/W2, is a ratio of the second depth D2 in relation to the second width W2. The second aspect ratio, D2/W2, is preferably in excess of 1 and not more than 5. The second aspect ratio, D2/W2, is in particular preferably not less than 3 and not more than 5. In this embodiment, the second aspect ratio, D2/W2, is equal to the first aspect ratio, D1/W1, of the first trench 22.

The second insulating film 33 covers an upper wall surface of the second trench 32. Specifically, the second insulating film 33 covers the upper wall surface of the second trench 32 which is positioned in a region on an opening side with respect to the bottom portion of the body region 20. The second insulating film 33 is in contact with the body region 20. The second insulating film 33 may be in contact with the drift region 7 in a region outside the body region 20. The second insulating film 33 faces the first insulating film 23 of the field trench structure 21 in a lateral direction (second direction Y) parallel to the first main surface 3. In this embodiment, the second insulating film 33 contains a silicon oxide. The second insulating film 33 is formed as a gate insulating film.

The second insulating film 33 has a second thickness T2 which is thinner than the first thickness T1 of the first insulating film 23. The second thickness T2 is a thickness of the second insulating film 33 along a normal direction of a wall surface of the second trench 32. The second thickness T2 may be not less than 0.01 μm and not more than 0.2 μm. The second thickness T2 may be not less than 0.01 μm and not more than 0.05 μm, not less than 0.05 μm and not more than 0.1 μm, not less than 0.1 μm and not more than 0.15 μm, or not less than 0.15 μm and not more than 0.2 μm. The second thickness T2 is preferably not less than 0.05 μm and not more than 0.1 μm.

The third insulating film 34 covers a lower wall surface of the second trench 32. Specifically, the third insulating film 34 covers the lower wall surface of the second trench 32 which is positioned in a region thereof on the bottom wall side with respect to the bottom portion of the body region 20. The third insulating film 34 demarcates a U-shaped recess space in a region on the bottom wall side of the second trench 32. The third insulating film 34 is in contact with the drift region 7. The third insulating film 34 faces the first insulating film 23 of the field trench structure 21 in the lateral direction (second direction Y) parallel to the first main surface 3. In this embodiment, the third insulating film 34 contains a silicon oxide.

The third insulating film 34 has a third thickness T3 which is thicker than the second thickness T2 of the second insulating film 33. The third thickness T3 is a thickness of the third insulating film 34 along a normal direction of the wall surface of the second trench 32. The third thickness T3 may be not less than 0.1 μm and not more than 1 μm. The third thickness T3 may be not less than 0.1 μm and not more than 0.25 μm, not less than 0.25 μm and not more than 0.5 μm, not less than 0.5 μm and not more than 0.75 μm, or not less than 0.75 μm and not more than 1 μm.

The third thickness T3 is preferably not less than 0.15 μm and not more than 0.65 μm. The third thickness T3 is preferably equal to the first thickness T1 of the first insulating film 23. The third thickness T3 being equal to the first thickness T1 means that a value of the third thickness T3 is within a range of ±10%, with a value of the first thickness T1 given as a reference.

The second electrode 35 is embedded at an upper side (opening side) inside the second trench 32 across the second insulating film 33. The second electrode 35 faces the body region 20 across the second insulating film 33. A bottom portion of the second electrode 35 is positioned on the bottom wall side of the second trench 32 with respect to the depth position of the bottom portion of the body region 20. The bottom portion of the second electrode 35 faces the drift region 7 across the third insulating film 34. A facing area of the second electrode 35 with respect to the body region 20 is larger than a facing area of the second electrode 35 with respect to the drift region 7.

The second electrode 35 faces the first electrode 24 of the field trench structure 21 in the lateral direction (second direction Y) parallel to the first main surface 3. In this embodiment, the second electrode 35 contains a conductive polysilicon. The second electrode 35 is formed as a gate electrode. A gate potential as a control potential is to be applied to the second electrode 35.

The third electrode 36 is embedded at a lower side (bottom wall side) inside the second trench 32 across the third insulating film 34. The third electrode 36 faces the drift region 7 across the third insulating film 34. The third electrode 36 faces the first electrode 24 of the field trench structure 21 in the lateral direction (second direction Y) parallel to the first main surface 3. In this embodiment, the third electrode 36 contains a conductive polysilicon. The third electrode 36 is formed as a field electrode. A source potential (for example, a ground potential) as a reference potential is to be applied to the third electrode 36. That is, in this embodiment, the third electrode 36 is fixed to the same potential as the first electrode 24.

The third electrode 36 includes one or a plurality of (three in this embodiment) lead-out electrodes 36A which are led out to the opening side of the second trench 32 across the third insulating film 34. In this embodiment, the plurality of lead-out electrodes 36A are formed in one end portion of the second trench 32 on one side (the third side surface 5C side), in the other end portion thereof on the other side (the fourth side surface 5D side), and in a central portion thereof. The lead-out electrode 36A in the central portion divides the third electrode 36 into two portions, the portion of the second trench 32 on one side (the third side surface 5C side) and the portion thereof on the other side (the fourth side surface 5D side).

With regard to the plurality of first trench gate structures 31A, the plurality of lead-out electrodes 36A are arrayed in a line in the second direction Y in a plan view and face each other. The arrangement and the number of the lead-out electrodes 36A are arbitrary and adjusted appropriately according to a length of the second trench 32 and a wiring layout.

The first intermediate insulating film 37 is interposed between the second electrode 35 and the third electrode 36 to insulate and separate the second electrode 35 and the third electrode 36. The first intermediate insulating film 37 continues to the second insulating film 33 and the third insulating film 34. The first intermediate insulating film 37 faces the first insulating film 23 of the field trench structure 21 in the lateral direction (second direction Y) parallel to the first main surface 3. In this embodiment, the first intermediate insulating film 37 contains a silicon oxide.

The first intermediate insulating film 37 has a first intermediate thickness TM1 which is thicker than the second thickness T2 of the second insulating film 33. The first intermediate thickness TM1 is a thickness of a portion of the first intermediate insulating film 37 along the normal direction Z. The first intermediate thickness TM1 may be not less than 0.05 μm and not more than 1 μm. The first intermediate thickness TM1 may be not less than 0.05 μm and not more than 0.1 μm, not less than 0.1 μm and not more than 0.25 μm, not less than 0.25 μm and not more than 0.5 μm, not less than 0.5 μm and not more than 0.75 μm, or not less than 0.75 μm and not more than 1 μm. The first intermediate thickness TM1 is preferably not less than 0.2 μm and not more than 0.5 μm.

The thickness of the first intermediate portion 37A of the first intermediate insulating film 37 which is interposed between the second electrode 35 and the third electrode 36 in a plan view can be adjusted appropriately by a layout of a resist mask used during manufacturing and is arbitrary. The thickness of the first intermediate portion 37A may be not less than 0.05 μm and not more than 15 μm. The thickness of the first intermediate portion 37A may be not less than 0.05 μm and not more than 1 μm, not less than 1 μm and not more than 5 μm, not less than 5 μm and not more than 10 μm, or not less than 10 μm and not more than 15 μm. The thickness of the first intermediate portion 37A is preferably not less than 3 μm and not more than 5 μm.

With reference to FIG. 7, the plurality of second trench gate structures 31B are formed in the second active region 12. The plurality of second trench gate structures 31B are formed at an interval from the pad region 16 and the second field trench structure 21B. The plurality of second trench gate structures 31B are each formed in a band shape extending in the first direction X in a plan view and formed, with the first interval P1 kept from each other in the second direction Y.

The plurality of second trench gate structures 31B are formed in a striped shape extending in the first direction X. That is, the plurality of second trench gate structures 31B extend in parallel with the second field trench structure 21B in a plan view. The plurality of second trench gate structures 31B are formed, with the second interval P2 kept from the second field trench structure 21B.

As with the first trench gate structure 31A, the plurality of second trench gate structures 31B each have a split electrode structure which includes a second trench 32, a second insulating film 33, a third insulating film 34, a second electrode 35, a third electrode 36, and a first intermediate insulating film 37. The second trench gate structure 31B has the same structure as the first trench gate structure 31A except for a difference in length of the second trench 32 and layout of the lead-out electrodes 36A (third electrode 36). A specific description of the second trench gate structure 31B will be omitted.

With reference to FIG. 7, the plurality of third trench gate structures 31C are formed in the third active region 13. The plurality of third trench gate structures 31C are formed at an interval from the pad region 16 and the third field trench structure 21C. The plurality of third trench gate structures 31C are each formed in a band shape extending in the first direction X in a plan view and formed, with the first interval P1 kept from each other in the second direction Y.

The plurality of third trench gate structures 31C are formed in a striped shape extending in the first direction X. That is, the plurality of third trench gate structures 31C extend in parallel with the third field trench structure 21C in a plan view. The plurality of third trench gate structures 31C are formed, with the second interval P2 kept from the third field trench structure 21C.

As with the first trench gate structure 31A, the plurality of third trench gate structures 31C each have a split electrode structure which includes a second trench 32, a second insulating film 33, a third insulating film 34, a second electrode 35, a third electrode 36, and a first intermediate insulating film 37. The third trench gate structure 31C has the same structure as the first trench gate structure 31A except for a difference in length of the second trench 32 and layout of the lead-out electrodes 36A (third electrode 36). A specific description of the third trench gate structure 31C will be omitted.

With reference to FIG. 3 and FIG. 4, the semiconductor device 1 includes a plurality of n⁺-type source regions 38 which are each formed in a region, of a surface layer portion of the body region 20, along the plurality of second trenches 32 (trench gate structures 31). Each of the source regions 38 has an n-type impurity concentration in excess of an n-type impurity concentration of the drift region 7. The n-type impurity concentration of each of the source regions 38 may be not less than 1×10¹⁸ cm⁻³ and not more than 1×10²¹ cm⁻³.

The plurality of source regions 38 are each formed in a band shape extending along the plurality of second trenches 32 in a plan view. Each of the source regions 38 covers a second insulating film 33 which is exposed from a corresponding second trench 32. That is, each of the source regions 38 faces the second electrode 35 across the second insulating film 33. A bottom portion of each of the source regions 38 is positioned in a region on the first main surface 3 side at an interval from the bottom portion of the body region 20. Each of the source regions 38 defines a channel of a MISFET with the drift region 7.

The semiconductor device 1 includes a plurality of source contact holes 39, each of which is formed in a region of the active region 10 between the plurality of second trenches 32 (trench gate structures 31). The plurality of source contact holes 39 are each formed in a band shape extending in the first direction X in a plan view. The plurality of source contact holes 39 are formed in a striped shape extending in the first direction X in a plan view.

The plurality of source contact holes 39 are formed alternately with the plurality of second trenches 32 along the second direction Y in a mode that one second trench 32 is held between them. In terms of the first direction X, a length of each of the source contact holes 39 is preferably less than the length of each of the second trenches 32. Each of the source contact holes 39 is formed at an interval from the second trench 32 in a plan view. Each of the source contact holes 39 is formed at a depth to traverse a source region 38. A bottom wall of each of the source contact holes 39 is positioned in a region between the bottom portion of the body region 20 and the bottom portion of the source region 38. Each of the source contact holes 39 exposes the source region 38 from both sides.

The semiconductor device 1 includes a plurality of p⁺-type contact regions 40, each of which is formed in a region along the plurality of source contact holes 39 inside the body region 20. Each of the contact regions 40 has a p-type impurity concentration in excess of the p-type impurity concentration of the body region 20. The p-type impurity concentration of each of the contact regions 40 may be not less than 1×10¹⁸ cm⁻³ and not more than 1×10²¹ cm⁻³.

Each of the contact regions 40 is formed in a region of the body region 20 which is along the bottom wall of each of the source contact holes 39. Each of the contact regions 40 is formed at an interval from the bottom portion of the body region 20 to the bottom wall side of each of the source contact holes 39. Each of the contact regions 40 covers an entire area of the bottom wall of each of the source contact holes 39. Each of the contact regions 40 may cover a side wall of each of the source contact holes 39. Each of the contact regions 40 is electrically connected to the plurality of source regions 38.

With reference to FIG. 2 to FIG. 7, the semiconductor device 1 includes a plurality of dummy trench gate structures 41 (third groove structures) which are formed in the first main surface 3 in the non-active region 14. The dummy trench gate structure 41 may be referred to as a “dummy trench structure.” The plurality of dummy trench gate structures 41 are constituted of accessory patterns which are electrically independent of the active region 10 (MISFET). The plurality of dummy trench gate structures 41 include one first dummy trench gate structure 41A, one second dummy trench gate structure 41B, and one third dummy trench gate structure 41C.

The first dummy trench gate structure 41A is formed in the non-active region 14 at an interval from the first field trench structure 21A to a side opposite to the first active region 11 and adjacent to the first field trench structure 21A. The first dummy trench gate structure 41A is formed in a band shape extending in the first direction X in a plan view. That is, the first dummy trench gate structure 41A extends in parallel with the first field trench structure 21A in a plan view and faces the first trench gate structure 31A across the first field trench structure 21A.

The first dummy trench gate structure 41A is formed, with a third interval P3 kept from the first field trench structure 21A. The third interval P3 may be not less than 0.1 μm and not more than 2 μm. The third interval P3 may be not less than 0.1 μm and not more than 0.5 μm, not less than 0.5 μm and not more than 1 μm, not less than 1 μm and not more than 1.5 μm, or not less than 1.5 μm and not more than 2 μm. The third interval P3 is preferably not less than 0.5 μm and not more than 1.5 μm.

The third interval P3 is preferably equal to the second interval P2 (first interval P1). The third interval P3 being equal to the second interval P2 (first interval P1) means that a value of the third interval P3 is within a range of ±10%, with a value of the second interval P2 (first interval P1) given as a reference.

The first dummy trench gate structure 41A has a dummy split electrode structure which includes a third trench 42 (third groove), a fourth insulating film 43, a fifth insulating film 44, a fourth electrode 45, a fifth electrode 46, and a second intermediate insulating film 47. The third trench 42, the fourth insulating film 43, the fifth insulating film 44, the fourth electrode 45, the fifth electrode 46, and the second intermediate insulating film 47 may be respectively referred to as a “dummy trench,” an “upper dummy insulating film,” a “lower dummy insulating film,” an “upper dummy electrode,” a “lower dummy electrode,” and a “dummy intermediate insulating film.” The third trench 42 is formed by digging down the first main surface 3 toward the second main surface 4. The third trench 42 traverses a depth position of the bottom portion of the body region 20 in terms of the thickness direction of the semiconductor chip 2 and is formed at an interval from the bottom portion of the drift region 7 to the first main surface 3 side.

An angle which is formed between a side wall of the third trench 42 and the first main surface 3 inside the semiconductor chip 2 may be not less than 90° and not more than 92°. The third trench 42 may be formed in a tapered shape in which an opening width is narrowed from an opening thereof to a bottom wall thereof. The bottom wall of the third trench 42 is preferably formed in a curved shape toward the second main surface 4.

The third trench 42 has a third width W3. The third width W3 is a width in a direction orthogonal to a direction in which the third trench 42 extends (that is, in the second direction Y). The third width W3 may be not less than 0.5 μm and not more than 3 μm. The third width W3 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The third width W3 is preferably not less than 0.5 μm and not more than 2 μm.

The third trench 42 has a third depth D3. The third depth D3 may be not less than 1 μm and not more than 10 μm. The third depth D3 may be not less than 1 μm and not more than 2 μm, not less than 2 μm and not more than 4 μm, not less than 4 μm and not more than 6 μm, not less than 6 μm and not more than 8 μm, or not less than 8 μm and not more than 10 μm. The third depth D3 is preferably not less than 1 μm and not more than 5 μm.

The third width W3 is preferably equal to the second width W2 of the second trench 32. The third width W3 being equal to the second width W2 means that a value of the third width W3 is within a range of ±10%, with a value of the second width W2 given as a reference. The third depth D3 is preferably equal to the second depth D2 of the second trench 32. The third depth D3 being equal to the second depth D2 means that a value of the third depth D3 is within a range of ±10%, with a value of the second depth D2 given as a reference.

The third trench 42 has a third aspect ratio, D3/W3. The third aspect ratio, D3/W3 is a ratio of the third depth D3 in relation to the third width W3. The third aspect ratio, D3/W3 is preferably in excess of 1 and not more than 5. The third aspect ratio, D3/W3 is in particular preferably not less than 3 and not more than 5. In this embodiment, the third aspect ratio of D3/W3 is equal to the second aspect ratio of D2/W2.

The fourth insulating film 43 covers an upper wall surface of the third trench 42. Specifically, the fourth insulating film 43 covers the upper wall surface of the third trench 42 positioned in a region on the opening side thereof with respect to the depth position of the bottom portion of the body region 20. The fourth insulating film 43 is in contact with the drift region 7. The fourth insulating film 43 faces the first insulating film 23 of the field trench structure 21 in the lateral direction (second direction Y) parallel to the first main surface 3. The fourth insulating film 43 faces the second insulating film 33 of the trench gate structure 31 across the field trench structure 21. In this embodiment, the fourth insulating film 43 contains a silicon oxide. The fourth insulating film 43 is formed as a dummy gate insulating film.

The fourth insulating film 43 has a fourth thickness T4 which is thinner than the first thickness T1 of the first insulating film 23. The fourth thickness T4 is a thickness of the fourth insulating film 43 along a normal direction of a wall surface of the third trench 42. The fourth thickness T4 may be not less than 0.01 μm and not more than 0.2 μm. The fourth thickness T4 may be not less than 0.01 μm and not more than 0.05 μm, not less than 0.05 μm and not more than 0.1 μm, not less than 0.1 μm and not more than 0.15 μm, or not less than 0.15 μm and not more than 0.2 μm. The fourth thickness T4 is preferably not less than 0.05 μm and not more than 0.1 μm.

The fourth thickness T4 is preferably equal to the second thickness T2 of the second insulating film 33. The fourth thickness T4 being equal to the second thickness T2 means that a value of the fourth thickness T4 is within a range of ±10%, with a value of the second thickness T2 given as a reference.

The fifth insulating film 44 covers a lower wall surface of the third trench 42. Specifically, the fifth insulating film 44 covers the lower wall surface of the third trench 42 positioned in a region thereof on the bottom wall side with respect to the depth position of the bottom portion of the body region 20. The fifth insulating film 44 demarcates a U-shaped recess space in a region on the bottom wall side of the third trench 42. The fifth insulating film 44 is in contact with the drift region 7. The fifth insulating film 44 faces the first insulating film 23 of the field trench structure 21 in the lateral direction (second direction Y) parallel to the first main surface 3. The fifth insulating film 44 faces the third insulating film 34 of the trench gate structure 31 across the field trench structure 21. In this embodiment, the fifth insulating film 44 contains a silicon oxide.

The fifth insulating film 44 has a fifth thickness T5 which is thicker than the fourth thickness T4 of the fourth insulating film 43. The fifth thickness T5 is a thickness of the fifth insulating film 44 along a normal direction of the wall surface of the third trench 42. The fifth thickness T5 may be not less than 0.1 μm and not more than 1 μm. The fifth thickness T5 may be not less than 0.1 μm and not more than 0.25 μm, not less than 0.25 μm and not more than 0.5 μm, not less than 0.5 μm and not more than 0.75 μm, or not less than 0.75 μm and not more than 1 μm.

The fifth thickness T5 is preferably not less than 0.15 μm and not more than 0.65 μm. The fifth thickness T5 is preferably equal to the third thickness T3 of the third insulating film 34. The fifth thickness T5 being equal to the third thickness T3 means that a value of the fifth thickness T5 is within a range of ±10%, with a value of the third thickness T3 given as a reference.

The fourth electrode 45 is embedded in an electrically floating state at an upper side of the third trench 42 across the fourth insulating film 43. The fourth electrode 45 is formed as a dummy gate electrode. A bottom portion of the fourth electrode 45 is positioned on the bottom wall side of the third trench 42 with respect to the depth position of the bottom portion of the body region 20. The fourth electrode 45 faces the drift region 7 across the fourth insulating film 43.

The fourth electrode 45 faces the first electrode 24 of the field trench structure 21 in the lateral direction (second direction Y) parallel to the first main surface 3. The fourth electrode 45 faces the second electrode 35 of the trench gate structure 31 across the field trench structure 21. In this embodiment, the fourth electrode 45 contains a conductive polysilicon.

The fifth electrode 46 is embedded in an electrically floating state at a lower side of the third trench 42 across the fifth insulating film 44. The fifth electrode 46 is formed as a dummy field electrode. The fifth electrode 46 faces the drift region 7 across the fifth insulating film 44. The fifth electrode 46 faces the first electrode 24 of the field trench structure 21 in the lateral direction (second direction Y) parallel to the first main surface 3. The fifth electrode 46 faces the third electrode 36 of the trench gate structure 31 across the field trench structure 21. In this embodiment, the fifth electrode 46 contains a conductive polysilicon.

The fifth electrode 46 includes one or a plurality of (three in this embodiment) lead-out electrodes 46A which are led out to the opening side of the third trench 42 across the fifth insulating film 44. In this embodiment, the plurality of lead-out electrodes 46A are formed in one end portion of the third trench 42 on one side (the third side surface 5C side), in the other end portion on the other side (the fourth side surface 5D side), and in a central portion thereof. The lead-out electrode 46A in the central portion divides the fourth electrode 45 into two portions, the portion of the third trench 42 on one side (the third side surface 5C side) and the portion thereof on the other side (the fourth side surface 5D side).

When a plurality of lines, each of which traverses the plurality of lead-out electrodes 36A of the plurality of trench gate structures 31 in the second direction Y, are set, the plurality of lead-out electrodes 46A are positioned on the plurality of lines. Thereby, the plurality of lead-out electrodes 46A face the plurality of lead-out electrodes 36A across the field trench structure 21 in a one-to-one correspondence relationship. The arrangement and the number of the lead-out electrodes 46A are arbitrary and adjusted appropriately according to a layout of the lead-out electrodes 36A (third electrode 36).

The second intermediate insulating film 47 is interposed between the fourth electrode 45 and the fifth electrode 46 to insulate and separate the fourth electrode 45 and the fifth electrode 46. The second intermediate insulating film 47 continues to the fourth insulating film 43 and the fifth insulating film 44. The second intermediate insulating film 47 faces the first insulating film 23 of the field trench structure 21 in the lateral direction (second direction Y) parallel to the first main surface 3. The second intermediate insulating film 47 faces the first intermediate insulating film 37 of the trench gate structure 31 across the field trench structure 21. In this embodiment, the second intermediate insulating film 47 contains a silicon oxide.

The second intermediate insulating film 47 has a second intermediate thickness TM2 which is thicker than the fourth thickness T4 of the fourth insulating film 43. The second intermediate thickness TM2 is a thickness of a portion of the second intermediate insulating film 47 along the normal direction Z. The second intermediate thickness TM2 may be not less than 0.05 μm and not more than 1 μm. The second intermediate thickness TM2 may be not less than 0.05 μm and not more than 0.1 μm, not less than 0.1 μm and not more than 0.25 μm, not less than 0.25 μm and not more than 0.5 μm, not less than 0.5 μm and not more than 0.75 μm, or not less than 0.75 μm and not more than 1 μm. The second intermediate thickness TM2 is preferably not less than 0.2 μm and not more than 0.5 μm.

The second intermediate thickness TM2 is preferably equal to the first intermediate thickness TM1 of the first intermediate insulating film 37. The second intermediate thickness TM2 being equal to the first intermediate thickness TM1 means that a value of the second intermediate thickness TM2 is within a range of ±10%, with a value of the first intermediate thickness TM1 given as a reference.

The thickness of the second intermediate portion 47A of the second intermediate insulating film 47 which is interposed between the fourth electrode 45 and the fifth electrode 46 in a plan view can be adjusted appropriately by a layout of a resist mask that is used during manufacturing and is arbitrary. The thickness of the second intermediate portion 47A may be not less than 0.05 μm and not more than 15 μm. The thickness of the second intermediate portion 47A may be not less than 0.05 μm and not more than 1 μm, not less than 1 μm and not more than 5 μm, not less than 5 μm and not more than 10 μm, or not less than 10 μm and not more than 15 μm. The thickness of the second intermediate portion 47A is preferably not less than 3 μm and not more than 5 μm.

The thickness of the second intermediate portion 47A is preferably equal to the thickness of the first intermediate portion 37A. The thickness of the second intermediate portion 47A being equal to the thickness of the first intermediate portion 37A means that a value of the thickness of the second intermediate portion 47A is within a range of ±10%, with a value of the thickness of the first intermediate portion 37A given as a reference.

The first dummy trench gate structure 41A demarcates a mesa portion 48 which is constituted of a part of the semiconductor chip 2 with the first field trench structure 21A. In the mesa portion 48, no body region 20 is formed in a surface layer portion of the first main surface 3. That is, the mesa portion 48 is constituted of the drift region 7 (epitaxial layer) and exposes the drift region 7 from the first main surface 3.

As described above, the first dummy trench gate structure 41A has a structure corresponding to the first trench gate structure 31A. That is, the third trench 42, the fourth insulating film 43, the fifth insulating film 44, the fourth electrode 45, the fifth electrode 46, and the second intermediate insulating film 47 of the first dummy trench gate structure 41A respectively correspond to the second trench 32, the second insulating film 33, the third insulating film 34, the second electrode 35, the third electrode 36, and the first intermediate insulating film 37 of the first trench gate structure 31A. Thereby, the first dummy trench gate structure 41A has a structure which is symmetrical to the first trench gate structure 31A (specifically, in line symmetry) across the first field trench structure 21A.

With reference to FIG. 7, the second dummy trench gate structure 41B is formed in the non-active region 14 at an interval from the second field trench structure 21B to the side opposite to the second active region 12 and adjacent to the second field trench structure 21B. The second dummy trench gate structure 41B is formed in a band shape extending in the first direction X in a plan view. That is, the second dummy trench gate structure 41B extends in parallel with the second field trench structure 21B in a plan view and faces the second trench gate structure 31B across the second field trench structure 21B. The second dummy trench gate structure 41B is formed, with the third interval P3 kept from the second field trench structure 21B, and demarcates the mesa portion 48 with the second field trench structure 21B.

As with the first dummy trench gate structure 41A, the second dummy trench gate structure 41B has a dummy split electrode structure which includes a third trench 42, a fourth insulating film 43, a fifth insulating film 44, a fourth electrode 45, a fifth electrode 46, and a second intermediate insulating film 47. The second dummy trench gate structure 41B has the same structure as the first dummy trench gate structure 41A except for a difference in length of the third trench 42 and layout of the lead-out electrodes 46A (fifth electrode 46).

The second dummy trench gate structure 41B has a structure corresponding to the second trench gate structure 31B. That is, the third trench 42, the fourth insulating film 43, the fifth insulating film 44, the fourth electrode 45, the fifth electrode 46, and the second intermediate insulating film 47 of the second dummy trench gate structure 41B respectively correspond to the second trench 32, the second insulating film 33, the third insulating film 34, the second electrode 35, the third electrode 36, and the first intermediate insulating film 37 of the second trench gate structure 31B. Thereby, the second dummy trench gate structure 41B has a structure which is symmetrical to the second trench gate structure 31B (specifically, in line symmetry) across the second field trench structure 21B. A specific description of the second dummy trench gate structure 41B will be omitted.

With reference to FIG. 7, the third dummy trench gate structure 41C is formed in the non-active region 14 at an interval from the third field trench structure 21C to the side opposite to the third active region 13 and adjacent to the third field trench structure 21C. The third dummy trench gate structure 41C is formed in a band shape extending in the first direction X in a plan view. That is, the third dummy trench gate structure 41C extends in parallel with the third field trench structure 21C in a plan view and faces the third trench gate structure 31C across the third field trench structure 21C. The third dummy trench gate structure 41C is formed, with the third interval P3 kept from the third field trench structure 21C, and demarcates the mesa portion 48 with the third field trench structure 21C.

As with the first dummy trench gate structure 41A, the third dummy trench gate structure 41C has a dummy split electrode structure which includes a third trench 42, a fourth insulating film 43, a fifth insulating film 44, a fourth electrode 45, a fifth electrode 46, and a second intermediate insulating film 47. The third dummy trench gate structure 41C has the same structure as the first dummy trench gate structure 41A except for a difference in length of the third trench 42 and layout of the lead-out electrodes 46A (fifth electrode 46).

The third dummy trench gate structure 41C has a structure corresponding to the third trench gate structure 31C. That is, the third trench 42, the fourth insulating film 43, the fifth insulating film 44, the fourth electrode 45, the fifth electrode 46, and the second intermediate insulating film 47 of the third dummy trench gate structure 41C respectively correspond to the second trench 32, the second insulating film 33, the third insulating film 34, the second electrode 35, the third electrode 36, and the first intermediate insulating film 37 of the third trench gate structure 31C. Thereby, the third dummy trench gate structure 41C has a structure which is symmetrical to the third trench gate structure 31C (specifically, in line symmetry) across the third field trench structure 21C. A specific description of the third dummy trench gate structure 41C will be omitted.

With reference to FIG. 4 to FIG. 6, the semiconductor device 1 includes a main surface insulating film 50 which covers the first main surface 3. The main surface insulating film 50 covers an entire area of the plurality of dummy trench gate structures 41 to insulate and separate the plurality of dummy trench gate structures 41 from outside. That is, the main surface insulating film 50 isolates the plurality of dummy trench gate structures 41 in an electrically floating state with the semiconductor chip 2. On the other hand, the main surface insulating film 50 selectively covers the plurality of field trench structures 21 and the plurality of trench gate structures 31 and allows them to be in contact from outside.

In this embodiment, the main surface insulating film 50 has a laminated structure which includes a first main surface insulating film 51 and a second main surface insulating film 52 laminated in this order from the first main surface 3 side. In this embodiment, the first main surface insulating film 51 contains a silicon oxide. The first main surface insulating film 51 covers the first main surface 3 and continues to the first insulating film 23, the second insulating film 33, the third insulating film 34, the fourth insulating film 43, and the fifth insulating film 44.

In this embodiment, the second main surface insulating film 52 contains a silicon oxide. The second main surface insulating film 52 selectively covers the plurality of field trench structures 21 and the plurality of trench gate structures 31 and also covers an entire area of the plurality of dummy trench gate structures 41. The second main surface insulating film 52 has a thickness in excess of a thickness of the first main surface insulating film 51.

The main surface insulating film 50 has a plurality of gate openings 53, a plurality of source openings 54, and a plurality of source contact openings 55 in a portion thereof that covers the active region 10. The plurality of gate openings 53 are each formed in a portion of the main surface insulating film 50 which covers the plurality of trench gate structures 31. The plurality of gate openings 53 expose each of the second electrodes 35 of the plurality of trench gate structures 31. The plurality of gate openings 53 may expose each of the one end portions and/or the other end portions of the plurality of trench gate structures 31. The plurality of gate openings 53 are preferably arrayed in a line at an interval in the second direction Y.

The plurality of source openings 54 are each formed in a portion of the main surface insulating film 50 which covers the plurality of field trench structures 21 and in a portion thereof which covers the plurality of trench gate structures 31. The plurality of source openings 54 expose each of the first electrodes 24 of the plurality of field trench structures 21 and each of the lead-out electrodes 36A (third electrodes 36) of the plurality of trench gate structures 31.

The plurality of source openings 54 are arrayed in a line at an interval in the second direction Y according to an arrangement of the lead-out electrodes 36A. In this embodiment, the plurality of source openings 54 expose only the plurality of lead-out electrodes 36A that are positioned in the central portion but do not expose the plurality of lead-out electrodes 36A that are positioned at both ends. That is, the plurality of lead-out electrodes 36A positioned at both ends are covered by the main surface insulating film 50.

The plurality of source contact openings 55 are each formed in a portion of the main surface insulating film 50 which covers a region between the plurality of trench gate structures 31. The plurality of source contact openings 55 expose each of the plurality of source contact holes 39 in a one-to-one correspondence relationship. The plurality of source contact openings 55 have a planar shape in agreement with the plurality of source contact holes 39 and are each communicatively connected to the plurality of source contact holes 39.

The semiconductor device 1 includes a plurality of gate plug electrodes 56 and a plurality of source plug electrodes 57 which are embedded in the main surface insulating film 50. The plurality of gate plug electrodes 56 are each embedded in the plurality of gate openings 53. The plurality of gate plug electrodes 56 are each electrically connected to the second electrode 35 of the trench gate structure 31 inside a corresponding gate opening 53.

The plurality of source plug electrodes 57 are each embedded in the plurality of source openings 54 and the plurality of source contact openings 55. The plurality of source plug electrodes 57 are each electrically connected to the first electrode 24 of the field trench structure 21 and the lead-out electrode 36A (third electrode 36) of the trench gate structure 31 inside a corresponding source opening 54. Further, the plurality of source plug electrodes 57 each enter the source contact hole 39 from a corresponding source contact opening 55 and are electrically connected to the source region 38 and the contact region 40.

The gate plug electrode 56 and the source plug electrode 57 have a laminated structure which includes a barrier electrode 58 and a main electrode 59 laminated in this order from the main surface insulating film 50 side. The barrier electrode 58 is formed as a film along the main surface insulating film 50 and demarcates a recess space. The barrier electrode 58 includes at least one of a Ti layer and a TiN layer. The main electrode 59 is embedded in the main surface insulating film 50 across the barrier electrode 58. The main electrode 59 contains tungsten.

With reference to FIG. 1, the semiconductor device 1 includes a gate main surface electrode 61 which is formed on the main surface insulating film 50. The gate main surface electrode 61 is electrically connected to the second electrodes 35 of the plurality of trench gate structures 31 via the plurality of gate plug electrodes 56. In FIG. 1, FIG. 2, FIG. 3, and FIG. 7, a connecting portion of the gate main surface electrode 61 to the second electrode 35 is indicated by a cross mark.

Specifically, the gate main surface electrode 61 integrally includes a gate pad electrode 62 and a gate finger electrode 63. The gate pad electrode 62 is an external terminal portion which is externally connected to a conductive wire (for example, bonding wire), etc. The gate pad electrode 62 is formed on a portion of the main surface insulating film 50 which covers the pad region 16 of the first main surface 3. Therefore, the gate pad electrode 62 is formed in a region which does not overlap with the field trench structure 21, the trench gate structure 31, or the dummy trench gate structure 41 in a plan view. The gate pad electrode 62 is formed in a quadrilateral shape in a plan view.

The gate finger electrode 63 is led out as a line onto the main surface insulating film 50 from the gate pad electrode 62 and demarcates an inner region of the first main surface 3 in a plurality of directions in a plan view. In this embodiment, the gate finger electrode 63 is formed in a C-shape extending along the first side surface 5A, the third side surface 5C and the fourth side surface 5D such as to demarcate the inner region of the first main surface 3 in three directions in a plan view and opens a region on the second side surface 5B side.

The gate finger electrode 63 is electrically connected to the plurality of gate plug electrode 56. The gate finger electrode 63 is electrically connected to the second electrodes 35 of the plurality of trench gate structures 31 via the plurality of gate plug electrodes 56. With regard to the first trench gate structure 31A, the gate finger electrode 63 is electrically connected to the second electrode 35 more inwardly than the plurality of lead-out electrodes 36A which are positioned at both ends in a plan view (refer to FIG. 3 as well).

The semiconductor device 1 includes a source main surface electrode 64 which is formed on the main surface insulating film 50 at an interval from the gate main surface electrode 61. The source main surface electrode 64 is electrically connected via the plurality of source plug electrodes 57 to the first electrodes 24 of the plurality of field trench structures 21, the lead-out electrodes 36A (third electrodes 36) of the plurality of trench gate structures 31, the source region 38, and the contact region 40. In FIG. 1, FIG. 2, FIG. 3, and FIG. 7, a connecting portion of a source pad electrode 65 to the first electrode 24 and the third electrode 36 is indicated by a cross mark.

Specifically, the source main surface electrode 64 includes the source pad electrode 65. The source pad electrode 65 is an external terminal portion which is externally connected to a conductive wire (for example, bonding wire), etc. The source pad electrode 65 is formed on a portion of the main surface insulating film 50 which covers the active region 10. The source pad electrode 65 is formed in a polygonal shape in a region which is demarcated by an inner peripheral edge of the gate main surface electrode 61 in a plan view.

The source pad electrode 65 is electrically connected to the plurality of source plug electrodes 57. The source pad electrode 65 is electrically connected via the plurality of source plug electrodes 57 to the first electrode 24 of the field trench structure 21 and the lead-out electrodes 36A (third electrodes 36) of the plurality of trench gate structures 31. Further, the source pad electrode 65 is electrically connected to the source region 38 and the contact region 40 via the plurality of source plug electrodes 57.

The gate main surface electrode 61 and the source main surface electrode 64 each include a barrier electrode 68 and a main electrode 69 laminated in this order from the main surface insulating film 50 side. The barrier electrode 68 is formed as a film on the main surface insulating film 50. The barrier electrode 68 includes at least one of a Ti layer and a TiN layer. The main electrode 69 is formed as a film on the barrier electrode 68. The main electrode 69 includes at least one of a pure Cu layer (Cu layer with a purity of not less than 99%), a pure Al layer (Al layer with a purity of not less than 99%), an AlSi alloy layer, an AlCu alloy layer, and an AlSiCu alloy layer.

The semiconductor device 1 includes a drain electrode 70 which is formed on the second main surface 4. The drain electrode 70 covers an entire area of the second main surface 4. The drain electrode 70 forms an ohmic contact with the second main surface 4 (drain region 6). The drain electrode 70 includes at least one of a Ti layer, an Ni layer, a Pd layer, an Au layer, and an Ag layer.

The drain electrode 70 may have a laminated structure in which at least two of a Ti layer, an Ni layer, a Pd layer, an Au layer, and an Ag layer are laminated in an arbitrary order. The drain electrode 70 may have a single layer structure which is constituted of a Ti layer, an Ni layer, a Pd layer, an Au layer or an Ag layer. The drain electrode 70 preferably includes a Ti layer serving as an ohmic electrode. In this embodiment, the drain electrode 70 has a laminated structure which includes a Ti layer, an Ni layer, a Pd layer, an Au layer, and an Ag layer laminated in this order from the second main surface 4 side.

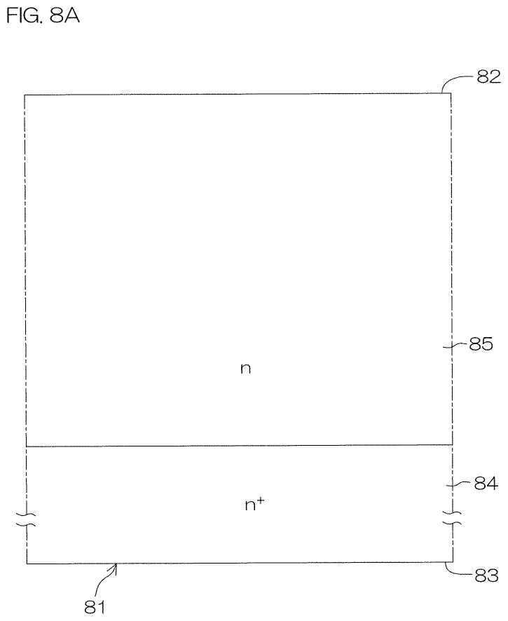

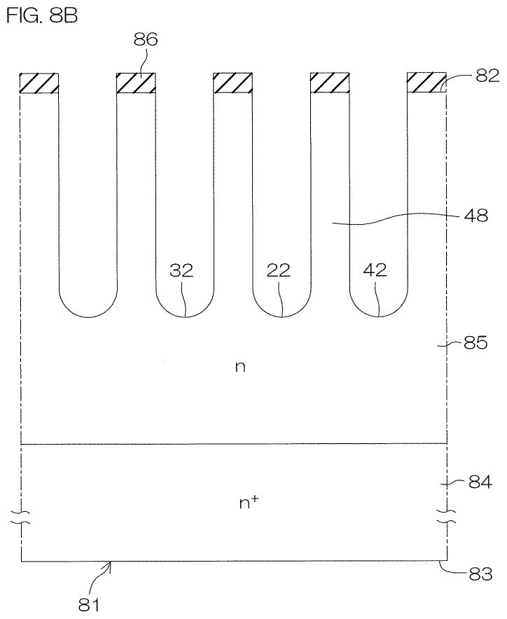

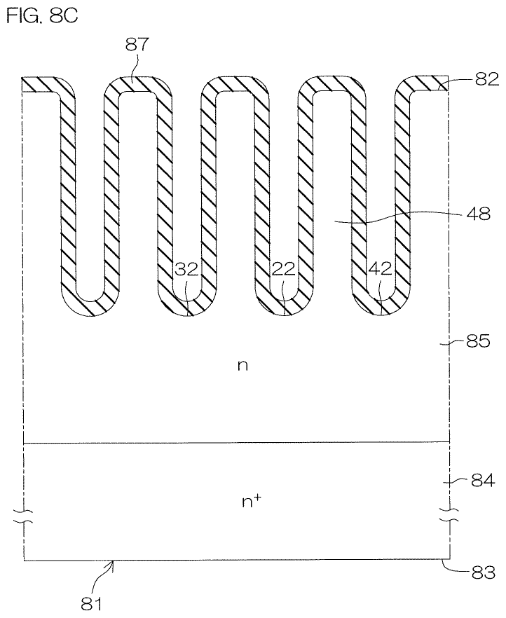

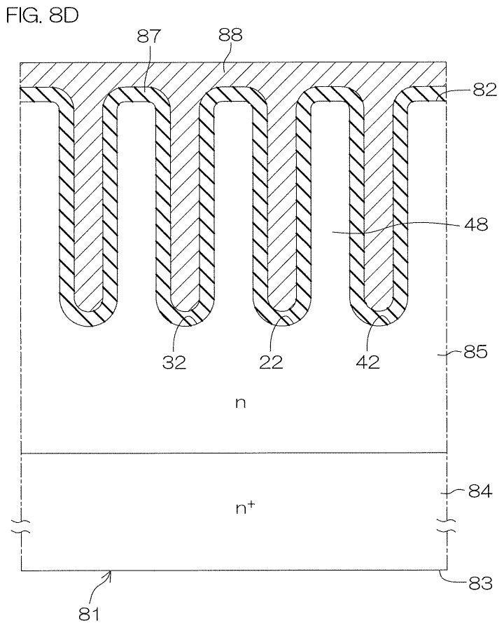

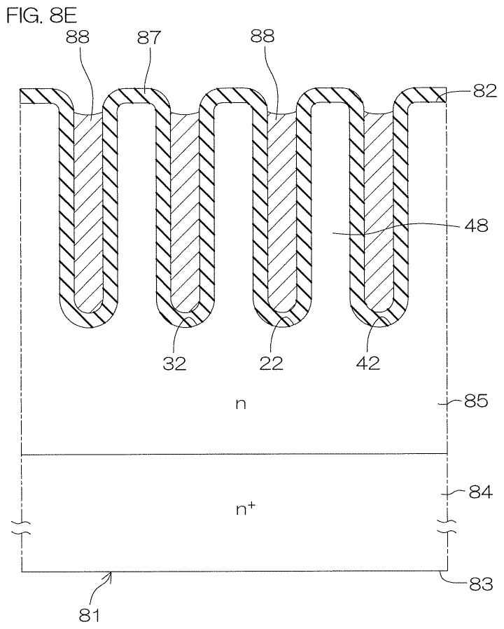

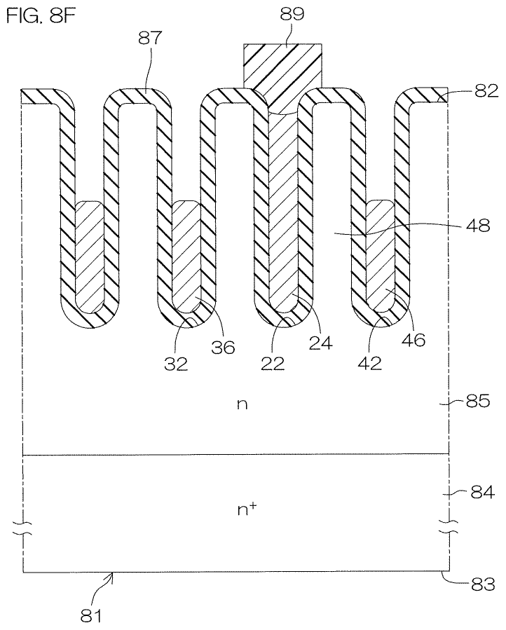

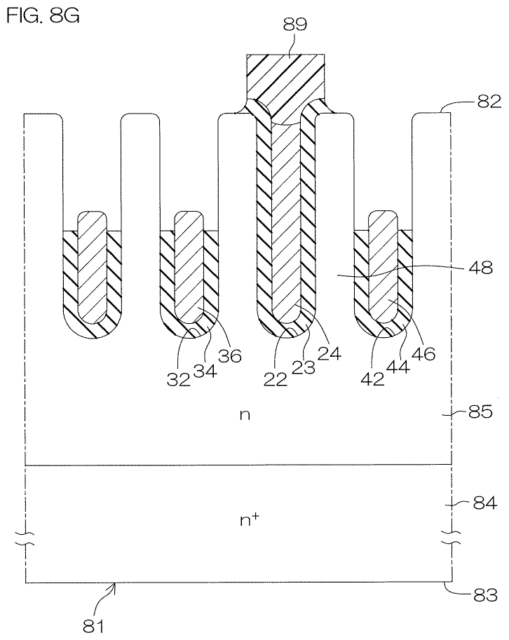

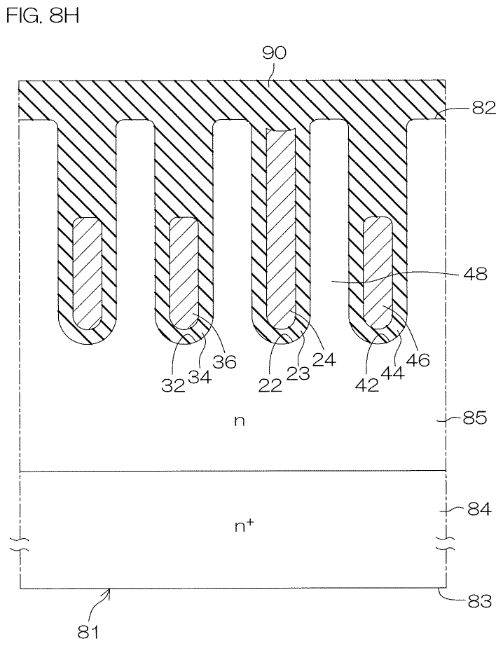

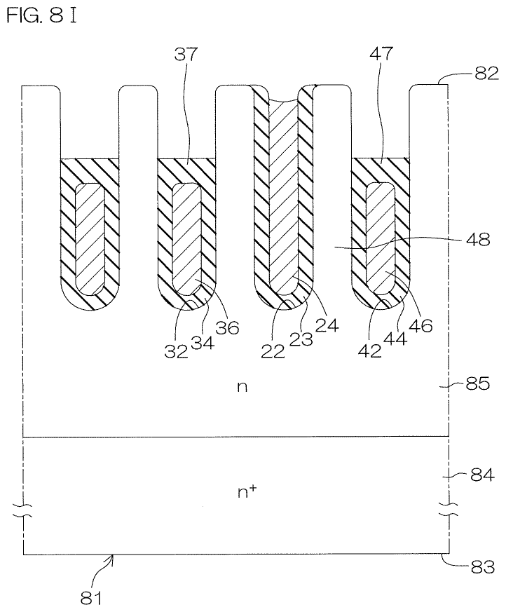

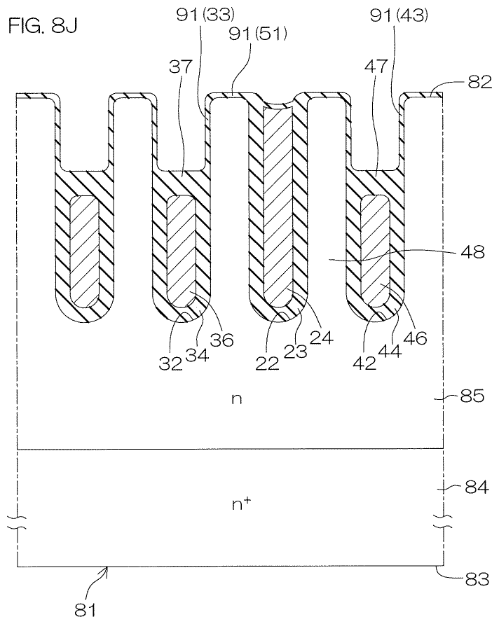

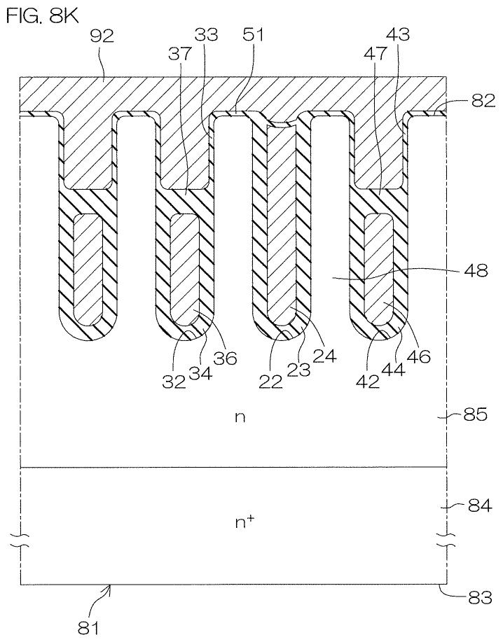

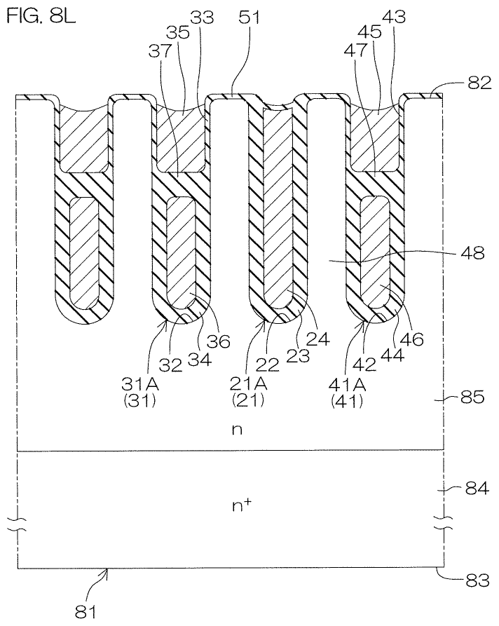

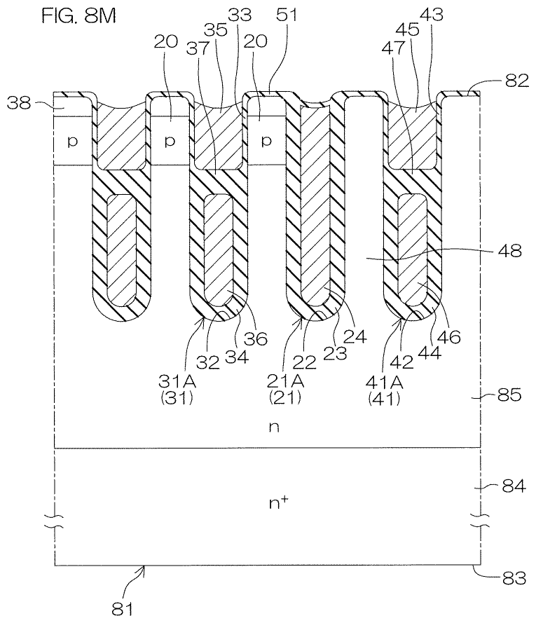

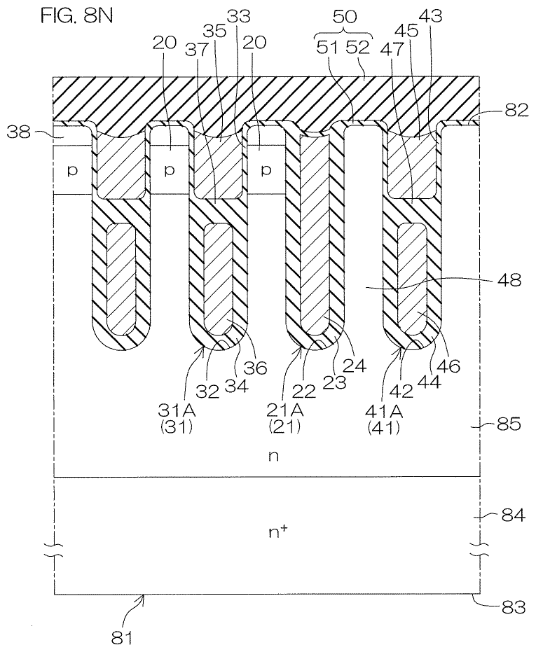

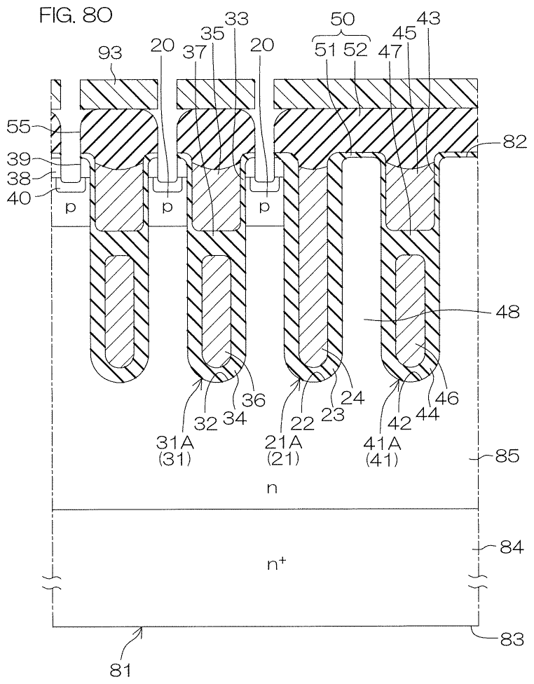

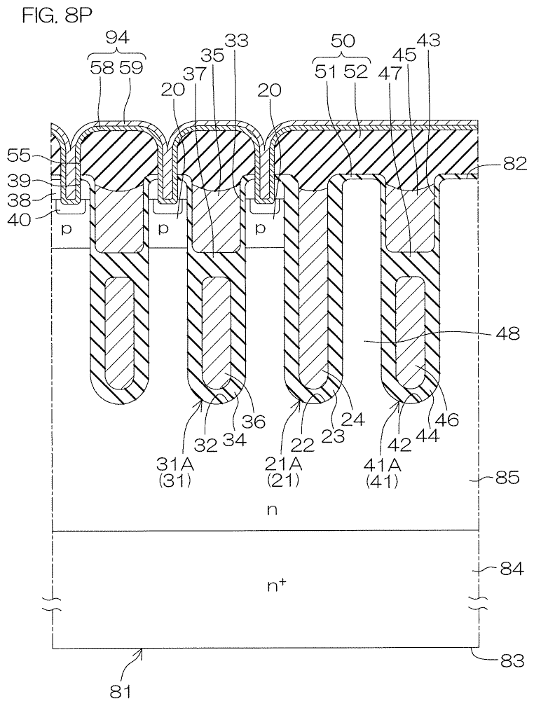

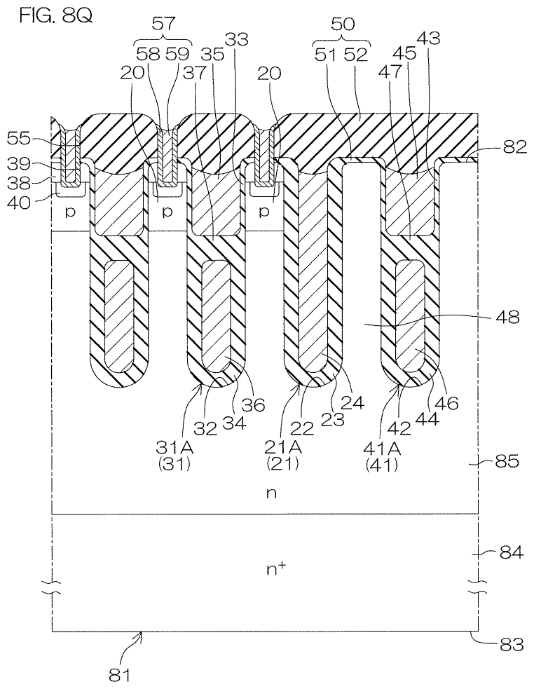

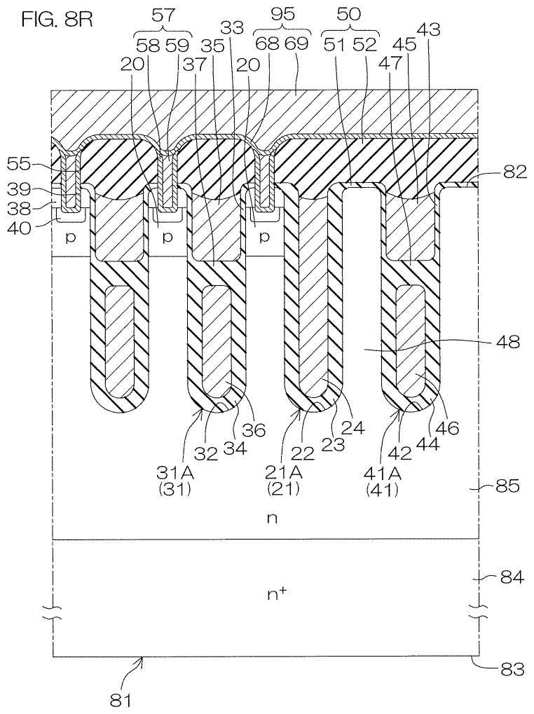

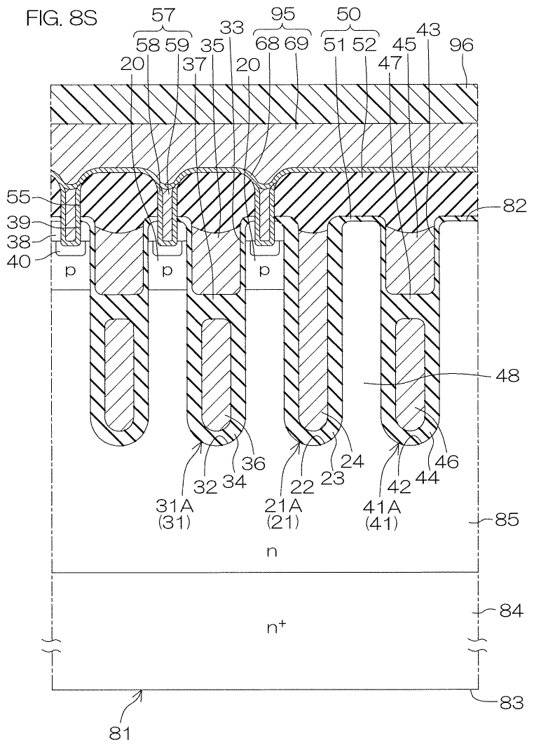

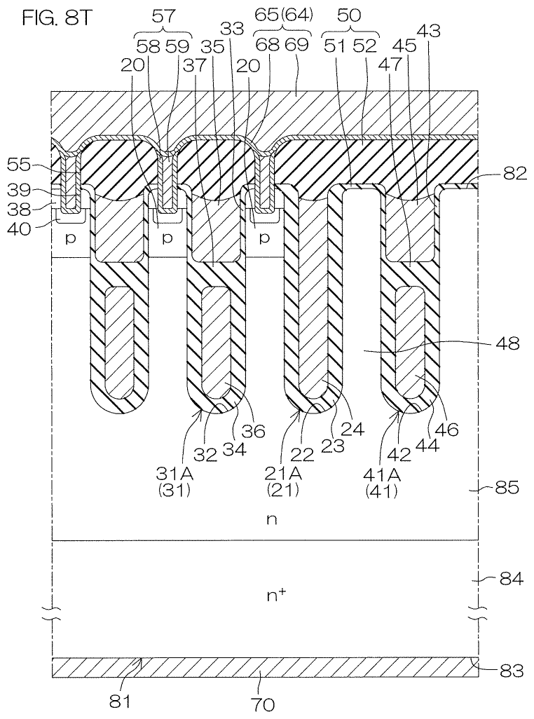

FIG. 8A to FIG. 8T are cross-sectional views for describing one example of a method for manufacturing the semiconductor device 1 shown in FIG. 1. FIG. 8A to FIG. 8T are each a cross-sectional view of a portion corresponding to that of FIG. 4.

With reference to FIG. 8A, an epitaxial wafer 81 which serves as a base of the semiconductor chip 2 is prepared. The epitaxial wafer 81 has a first wafer main surface 82 on one side and a second wafer main surface 83 on the other side. The first wafer main surface 82 and the second wafer main surface 83 respectively correspond to the first main surface 3 and the second main surface 4 of the semiconductor chip 2.

The epitaxial wafer 81 has a laminated structure which includes an n⁺-type semiconductor wafer 84 and an n-type epitaxial layer 85. The epitaxial layer 85 is formed by epitaxial growth of silicon from a main surface of the semiconductor wafer 84. The semiconductor wafer 84 serves as a base of the drain region 6, and the epitaxial layer 85 serves as a base of the drift region 7.

Next, with reference to FIG. 8B, a hard mask 86 having a predetermined pattern is formed on the first wafer main surface 82. The hard mask 86 exposes regions of the first wafer main surface 82 in which a plurality of first trenches 22, a plurality of second trenches 32, and a plurality of third trenches 42 are to be formed and covers the other regions. The hard mask 86 may be formed by a CVD (Chemical Vapor Deposition) method or an oxidation treatment method (for example, a thermal oxidation treatment method). The hard mask 86 may be subjected to patterning by an etching method via a resist mask (not shown).

Next, an unnecessary portion of the first wafer main surface 82 is removed by an etching method via the hard mask 86. The etching method may be a wet etching method and/or a dry etching method. Thereby, the plurality of first trenches 22, the plurality of second trenches 32, and the plurality of third trenches 42 are formed in the first wafer main surface 82. The hard mask 86 is thereafter removed.

Next, with reference to FIG. 8C, a first base insulating film 87 is formed on the first wafer main surface 82. The first base insulating film 87 serves as a base of the first insulating film 23, the third insulating film 34, and the fifth insulating film 44. The first base insulating film 87 is formed as a film along the first wafer main surface 82, wall surfaces of the plurality of first trenches 22, wall surfaces of the plurality of second trenches 32, and wall surfaces of the plurality of third trenches 42. The first base insulating film 87 may be formed by a CVD method and/or an oxidation treatment method (for example, thermal oxidation treatment method).

Next, with reference to FIG. 8D, a first base electrode layer 88 is formed on the first base insulating film 87. The first base electrode layer 88 contains a conductive polysilicon and serves as a base of the first electrode 24, the third electrode 36, and the fifth electrode 46. The first base electrode layer 88 fills the plurality of first trenches 22, the plurality of second trenches 32, and the plurality of third trenches 42 across the first base insulating film 87 and covers the first wafer main surface 82. The first base electrode layer 88 may be formed by a CVD method.

Next, with reference to FIG. 8E, an unnecessary portion of the first base electrode layer 88 is removed by an etching method until the first base insulating film 87 is exposed. The etching method may be a wet etching method and/or a dry etching method.

Next, with reference to FIG. 8F, a resist mask 89 having a predetermined pattern is formed on the first wafer main surface 82. The resist mask 89 covers the plurality of first trenches 22 and exposes the plurality of second trenches 32 and the plurality of third trenches 42. Next, an unnecessary portion of the first base electrode layer 88 is removed by an etching method via the resist mask 89. The etching method may be a wet etching method and/or a dry etching method. Thereby, the first electrode 24, the third electrode 36 and the fifth electrode 46 are formed.

Next, with reference to FIG. 8G, an unnecessary portion of the first base insulating film 87 is removed by an etching method via the resist mask 89. The etching method may be a wet etching method and/or a dry etching method. Thereby, the first insulating film 23, the third insulating film 34, and the fifth insulating film 44 are formed. The resist mask 89 is thereafter removed.

Next, with reference to FIG. 8H, a second base insulating film 90 is formed on the first wafer main surface 82. The second base insulating film 90 contains a silicon oxide and serves as a base of the first intermediate insulating film 37 and the second intermediate insulating film 47. The second base insulating film 90 fills the plurality of second trenches 32 and the plurality of third trenches 42 and covers the first wafer main surface 82. The second base insulating film 90 may be formed by a CVD method.

Next, with reference to FIG. 8I, an unnecessary portion of the second base insulating film 90 is removed by an etching method until the first wafer main surface 82 is exposed. The etching method may be a wet etching method and/or a dry etching method.

Next, an unnecessary portion of the second base insulating film 90 is removed by an etching method via a resist mask (not shown) until the side walls of the plurality of second trenches 32 and the side walls of the plurality of third trenches 42 are exposed. The etching method may be a wet etching method and/or a dry etching method. Thereby, the first intermediate insulating film 37 and the second intermediate insulating film 47 are formed. The thickness of the first intermediate portion 37A of the first intermediate insulating film 37 and the thickness of the second intermediate portion 47A of the second intermediate insulating film 47 are each adjusted to an arbitrary value by a layout of a resist mask (not shown).

Next, with reference to FIG. 8J, a third base insulating film 91 is formed as a film along the first wafer main surface 82, the wall surfaces of the plurality of second trenches 32, and the wall surfaces of the plurality of third trenches 42. The third base insulating film 91 serves as a base of the second insulating film 33, the fourth insulating film 43, and the first main surface insulating film 51. The third base insulating film 91 is also formed on an outer surface of the first electrode 24. The third base insulating film 91 may be formed by a CVD method and/or an oxidation treatment method (for example, thermal oxidation treatment method).

Next, with reference to FIG. 8K, a second base electrode layer 92 is formed on the third base insulating film 91. The second base electrode layer 92 contains a conductive polysilicon and serves as a base of the second electrode 35 and the fourth electrode 45. The second base electrode layer 92 fills the plurality of second trenches 32 and the plurality of third trenches 42 across the third base insulating film 91 and covers the first wafer main surface 82. The second base electrode layer 92 may be formed by a CVD method.

Next, with reference to FIG. 8L, an unnecessary portion of the second base electrode layer 92 is removed by an etching method until the first main surface insulating film 51 is exposed. The etching method may be a wet etching method and/or a dry etching method. Thereby, the second electrode 35 and the fourth electrode 45 are formed. Further, the plurality of field trench structures 21, the plurality of trench gate structures 31, and the plurality of dummy trench gate structures 41 are formed.

Next, with reference to FIG. 8M, a body region 20 is formed in a surface layer portion of the first wafer main surface 82. The body region 20 is formed by an ion implantation method via an ion implantation mask (not shown) through introduction of a p-type impurity into the surface layer portion of the first wafer main surface 82. Specifically, the p-type impurity of the body region 20 is introduced into the surface layer portion of the first wafer main surface 82 from the first wafer main surface 82 and the side wall of the second trench 32.

Further, a source region 38 is formed in the surface layer portion of the first wafer main surface 82. The source region 38 is formed by an ion implantation method via an ion implantation mask (not shown) through introduction of an n-type impurity into the surface layer portion of the first wafer main surface 82. Specifically, the n-type impurity of the source region 38 is introduced into the surface layer portion of the first wafer main surface 82 from the first wafer main surface 82 and the side wall of the second trench 32. The source region 38 may be formed after a forming step of the body region 20 or may be formed prior to the forming step of the body region 20.

Next, with reference to FIG. 8N, a second main surface insulating film 52 is formed on the first main surface insulating film 51. The second main surface insulating film 52 collectively covers the plurality of field trench structures 21, the plurality of trench gate structures 31, and the plurality of dummy trench gate structures 41. The second main surface insulating film 52 contains a silicon oxide. The second main surface insulating film 52 may be formed by a CVD method. Thereby, the main surface insulating film 50 which includes the first main surface insulating film 51 and the second main surface insulating film 52 is formed.

Next, with reference to FIG. 8O, a resist mask 93 having a predetermined pattern is formed on the main surface insulating film 50. The resist mask 93 exposes regions of the main surface insulating film 50 in which a plurality of gate openings 53, a plurality of source openings 54, and a plurality of source contact openings 55 are to be formed and covers the other regions.

Next, an unnecessary portion of the main surface insulating film 50 is removed by an etching method via the resist mask 93. The etching method may be a wet etching method and/or a dry etching method. Thereby, the plurality of gate openings 53, the plurality of source openings 54 and the plurality of source contact openings 55 are formed in the main surface insulating film 50.

Next, a portion of the first wafer main surface 82 which is exposed from the plurality of source contact openings 55 is removed by an etching method via the plurality of source contact openings 55. The etching method may be a wet etching method and/or a dry etching method. Thereby, the plurality of source contact holes 39 which are communicatively connected to the plurality of source contact openings 55 are formed in the first wafer main surface 82. The resist mask 93 may be removed after formation of the source contact holes 39 or may be removed after formation of the source contact openings 55.

Next, a contact region 40 is formed in a region which is along a bottom wall of the source contact hole 39 in the surface layer portion of the body region 20. The contact region 40 is formed by an ion implantation method via an ion implantation mask (not shown) through introduction of a p-type impurity into the bottom wall of the source contact hole 39.

Next, with reference to FIG. 8P, a third base electrode layer 94 is formed on the main surface insulating film 50. The third base electrode layer 94 serves as a base of the plurality of gate plug electrodes 56 and the plurality of source plug electrodes 57. The third base electrode layer 94 includes a barrier electrode 58 and a main electrode 59 laminated in this order from the main surface insulating film 50 side. The barrier electrode 58 includes at least one of a Ti layer and a TiN layer. The main electrode 59 contains tungsten. The barrier electrode 58 and the main electrode 59 may each be formed by a sputtering method and/or a vapor deposition method.

Next, with reference to FIG. 8Q, an unnecessary portion of the third base electrode layer 94 is removed by an etching method until the main surface insulating film 50 is exposed. The etching method may be a wet etching method and/or a dry etching method. Thereby, the plurality of gate plug electrodes 56 and the plurality of source plug electrodes 57 are formed.

Next, with reference to FIG. 8R, a fourth base electrode layer 95 is formed on the main surface insulating film 50. The fourth base electrode layer 95 serves as a base of the gate main surface electrode 61 and the source main surface electrode 64. The fourth base electrode layer 95 includes a barrier electrode 68 and a main electrode 69 laminated in this order from the main surface insulating film 50 side. The barrier electrode 68 includes at least one of a Ti layer and a TiN layer. The main electrode 69 includes at least one of a pure Cu layer, a pure Al layer, an AlSi alloy layer, an AlCu alloy layer, and an AlSiCu alloy layer. The barrier electrode 68 and the main electrode 69 may each be formed by a sputtering method and/or a vapor deposition method.

Next, with reference to FIG. 8S, a resist mask 96 having a predetermined pattern is formed on the fourth base electrode layer 95. The resist mask 96 covers regions of the fourth base electrode layer 95 in which the gate main surface electrode 61 and the source main surface electrode 64 are to be formed and exposes the other regions. Next, an unnecessary portion of the fourth base electrode layer 95 is removed by an etching method via the resist mask 96. The etching method may be a wet etching method and/or a dry etching method. Thereby, the gate main surface electrode 61 and the source main surface electrode 64 are formed.

Next, with reference to FIG. 8T, a drain electrode 70 is formed on the second wafer main surface 83. The drain electrode 70 includes at least one of a Ti layer, an Ni layer, a Pd layer, an Au layer, and an Ag layer. The drain electrode 70 may be formed by a sputtering method and/or a vapor deposition method. Thereafter, the epitaxial wafer 81 is selectively cut and the plurality of semiconductor devices 1 are cut out. The semiconductor device 1 is manufactured through the steps including the above.

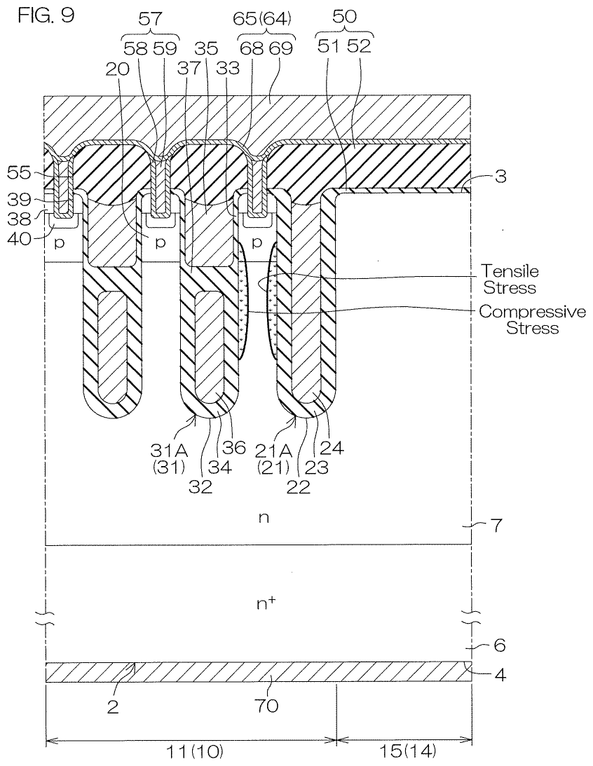

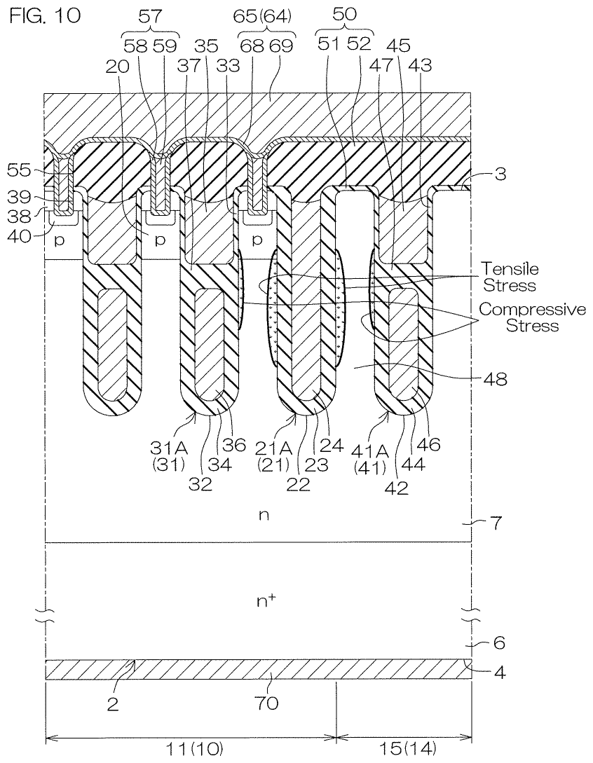

FIG. 9 is a drawing corresponding to FIG. 4 and a cross-sectional view for describing a stress where no dummy trench gate structure 41 is present. FIG. 10 is a drawing corresponding to FIG. 4 and a cross-sectional view for describing a stress where the dummy trench gate structure 41 is present.

With reference to FIG. 9, in the case where no dummy trench gate structure 41 is present, the field trench structure 21 and the trench gate structure 31, each of which has the mutually different internal structure, are formed such as to be adjacent to each other. Specifically, the field trench structure 21 includes the first trench 22 and the first insulating film 23. The first insulating film 23 has the relatively thick first thickness T1 and is formed on the wall surface of the first trench 22. The field trench structure 21 has the single electrode structure which includes the first electrode 24. The first electrode 24 is embedded in the first trench 22 across the first insulating film 23.

On the other hand, the trench gate structure 31 includes the second trench 32, the second insulating film 33, and the third insulating film 34. The second insulating film 33 has the second thickness T2 which is thinner than the first thickness T1 and is formed in the upper wall surface of the second trench 32. The third insulating film 34 has the third thickness T3 which is thicker than the second thickness T2 and is formed in the lower wall surface of the second trench 32.

The trench gate structure 31 has the split electrode structure which includes the second electrode 35, the third electrode 36, and the first intermediate insulating film 37. The second electrode 35 is embedded at the upper side inside the second trench 32 across the second insulating film 33. The third electrode 36 is embedded at the lower side inside the second trench 32 across the third insulating film 34. The first intermediate insulating film 37 is interposed between the second electrode 35 and the third electrode 36 to insulate the second electrode 35 and the third electrode 36.

In the case of the above structure, a stress occurs in a region of the semiconductor chip 2 between the field trench structure 21 and the trench gate structure 31. The stress occurs due to a difference in thickness between the first insulating film 23 inside the first trench 22 and the second insulating film 33 (third insulating film 34) inside the second trench 32. The stress occurs in a direction to draw the first trench 22 to the second trench 32 side. That is, the stress includes a tensile stress on the first trench 22 side and a compressive stress on the second trench 32 side. This type of stress will cause a crystal defect in the region between the first trench 22 and the second trench 32.

With reference to FIG. 10, in the semiconductor device 1, in order to avoid problems resulting from the stress, the dummy trench gate structure 41 having the structure corresponding to the trench gate structure 31 is formed in the region (non-active region 14) which faces the trench gate structure 31 across the field trench structure 21. In this case, while the trench gate structure 31 is formed such as to be adjacent to the field trench structure 21, the dummy trench gate structure 41 is formed such as to be adjacent to the field trench structure 21.

According to the above structure, while a first stress is allowed to occur in a region of the semiconductor chip 2 on the trench gate structure 31 side, a second stress is allowed to occur in a region of the semiconductor chip 2 on the dummy trench gate structure 41 side. While the first stress occurs in a direction to draw the first trench 22 to the second trench 32 side, the second stress occurs in a direction to draw the first trench 22 to the third trench 42 side. That is, the second stress occurs in a direction to cancel out the first stress. The first stress and the second stress can be thereby eased, thus making it possible to suppress a crystal defect resulting from the stress.

Specifically, the dummy trench gate structure 41 includes the third trench 42, the fourth insulating film 43, and the fifth insulating film 44. The fourth insulating film 43 has the fourth thickness T4 which is thinner than the first thickness T1 and is formed in an upper wall surface of the third trench 42. The fifth insulating film 44 has the fifth thickness T5 which is thicker than the fourth thickness T4 and is formed in the lower wall surface of the third trench 42.

The dummy trench gate structure 41 has the dummy split electrode structure which includes a fourth electrode 45, the fifth electrode 46, and the second intermediate insulating film 47. The fourth electrode 45 is embedded at the upper side inside the third trench 42 across the fourth insulating film 43. The fifth electrode 46 is embedded at the lower side inside the third trench 42 across the fifth insulating film 44. The second intermediate insulating film 47 is interposed between the fourth electrode 45 and the fifth electrode 46 to insulate the fourth electrode 45 and the fifth electrode 46.

The third trench 42, the fourth insulating film 43, the fifth insulating film 44, the fourth electrode 45, the fifth electrode 46, and the second intermediate insulating film 47 of the dummy trench gate structure 41 respectively correspond to the second trench 32, the second insulating film 33, the third insulating film 34, the second electrode 35, the third electrode 36, and the first intermediate insulating film 37 of the trench gate structure 31.

The fourth electrode 45 and the fifth electrode 46 are preferably formed in an electrically floating state. In this case, since no electric power is supplied to the fourth electrode 45 or the fifth electrode 46, it is possible to suppress an undesired change in electrical characteristics resulting from the dummy trench gate structure 41. As an example, it is possible to suppress an undesired increase in current leakage and an undesired increase in parasitic capacitance resulting from the dummy trench gate structure 41.

In particular, according to a structure in which the dummy trench gate structure 41 is arranged in the non-active region 14, it is possible to suppress a crystal defect in the active region 10 and also possible to appropriately suppress a change in electrical characteristics in the active region 10. The mesa portion 48 between the field trench structure 21 and the dummy trench gate structure 41 is preferably free of the body region 20. According to the above structure, it is possible to appropriately suppress a change in electrical characteristics resulting from the structure of the mesa portion 48.

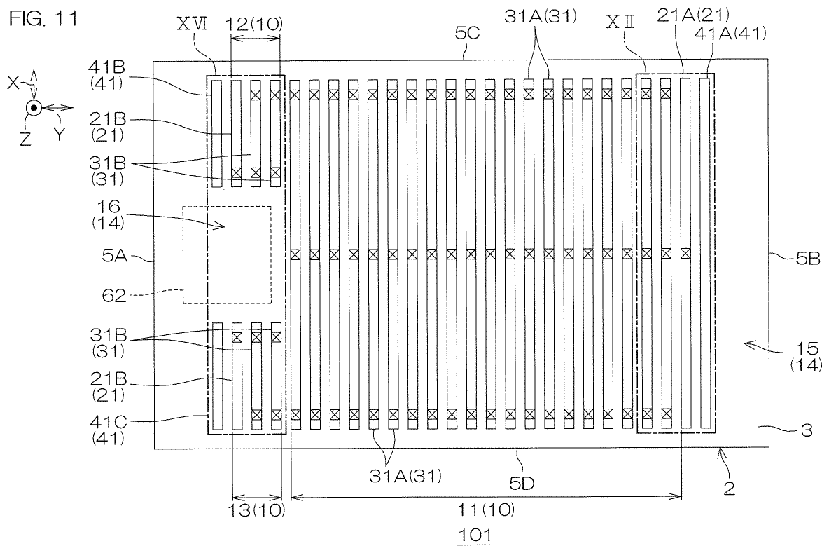

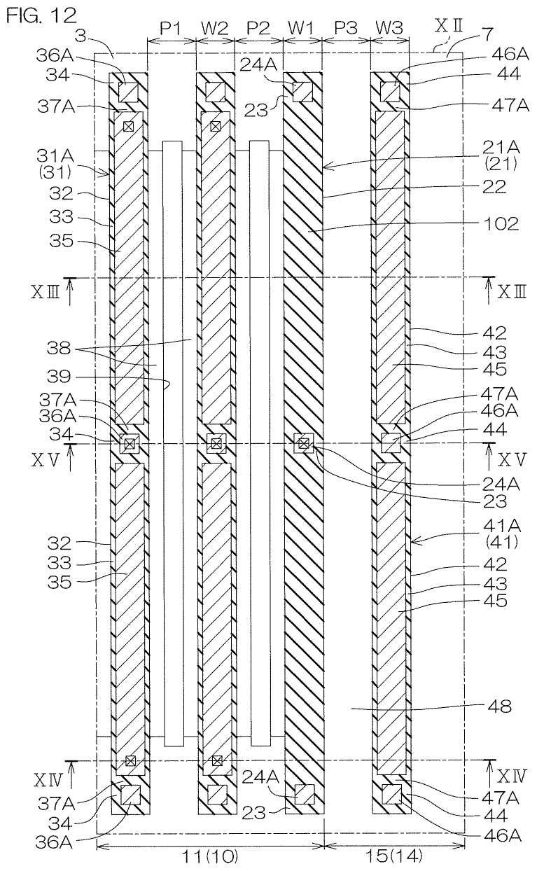

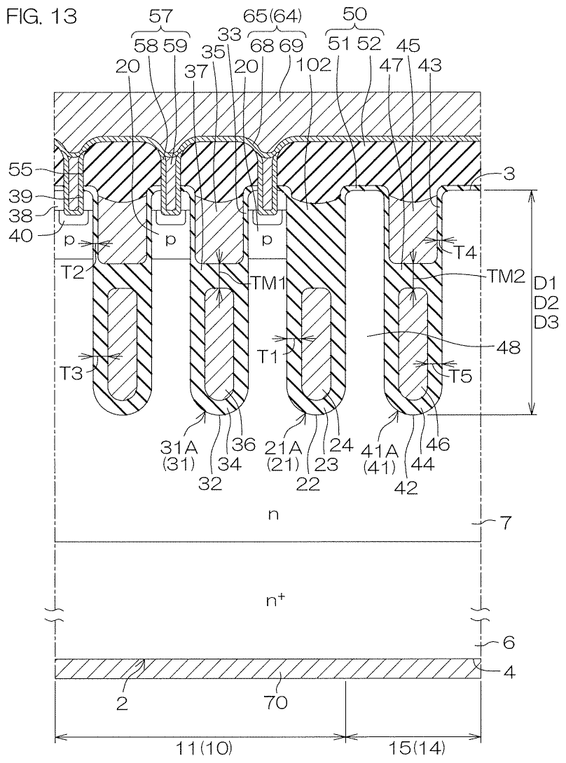

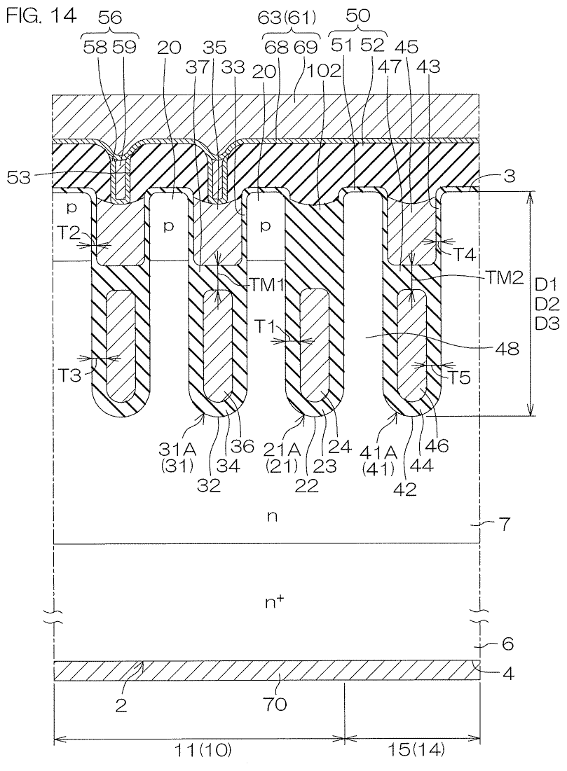

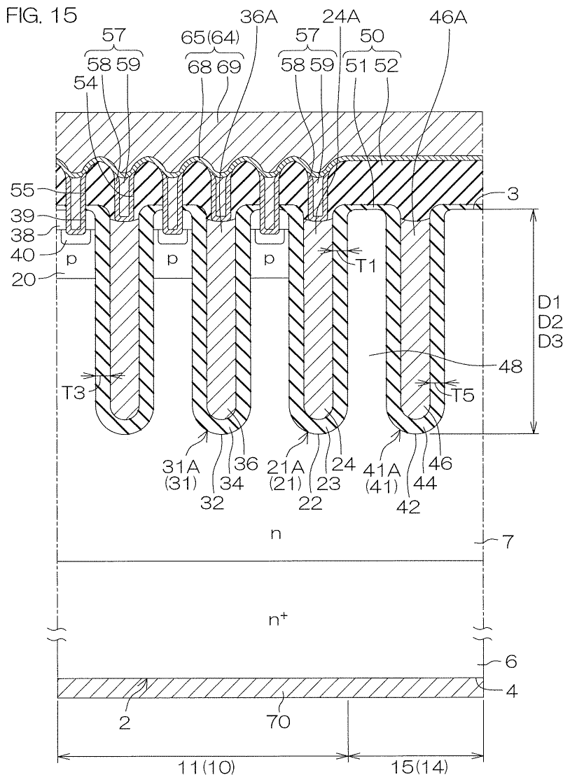

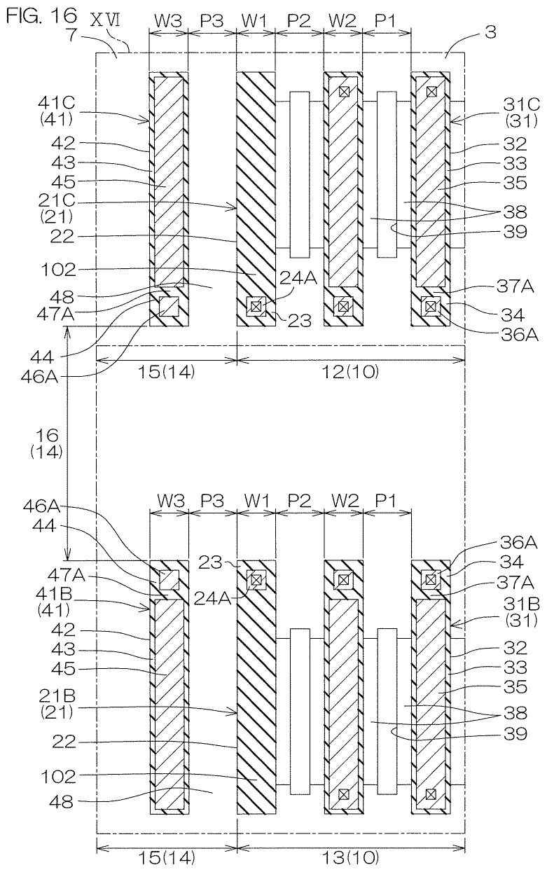

FIG. 11 is a drawing corresponding to FIG. 2 and a plan view showing a structure of the first main surface 3 of the semiconductor chip 2 of a semiconductor device 101 according to the second embodiment of the present invention. FIG. 12 is an enlarged view of a region XII shown in FIG. 11. FIG. 13 is a cross-sectional view along line XIII-XIII shown in FIG. 12. FIG. 14 is a cross-sectional view along line XIV-XIV shown in FIG. 12. FIG. 15 is a cross-sectional view along line XV-XV shown in FIG. 12. FIG. 16 is an enlarged view of a region XVI shown in FIG. 11. Hereinafter, a structure corresponding to the structure described for the semiconductor device 1 is given the same reference sign, and a description thereof will be omitted.

With reference to FIG. 11 to FIG. 16, in this embodiment, the first field trench structure 21A according to the semiconductor device 101 has a single electrode structure which includes the first trench 22, the first insulating film 23, the first electrode 24, and an insulator 102. The insulator 102 may be referred to as a “field insulator.” The first trench 22 is formed in the same mode as in the case of the first embodiment.

The first insulating film 23 is formed as a film along a lower wall surface of the first trench 22 and exposes an upper wall surface of the first trench 22. Specifically, the first insulating film 23 covers the lower wall surface of the first trench 22 positioned in a region thereof on the bottom wall side with respect to the bottom portion of the body region 20. A part of the first insulating film 23 may be in contact with the body region 20. The first insulating film 23 demarcates a U-shaped recess space in a region on the bottom wall side of the first trench 22. The first insulating film 23 is in contact with the drift region 7. As with the first embodiment, the first insulating film 23 has the first thickness T1.

The first electrode 24 is embedded at a lower side inside the first trench 22 across the first insulating film 23. Specifically, the first electrode 24 is embedded in a region on the bottom wall side of the first trench 22 with respect to the bottom portion of the body region 20. The first electrode 24 faces the drift region 7 across the first insulating film 23. A part of the first electrode 24 may face the body region 20 across the first insulating film 23.

The first electrode 24 includes one or a plurality of (three in this embodiment) lead-out electrodes 24A which are led out to an opening side of the first trench 22 across the first insulating film 23. In this embodiment, the plurality of lead-out electrodes 24A are formed in one end portion of the first trench 22 on one side (the third side surface 5C side), in the other end portion on the other side (the fourth side surface 5D side), and in a central portion thereof in a plan view. The arrangement and the number of the lead-out electrodes 24A are arbitrary and adjusted appropriately according to a length of the first trench 22, a wiring layout, a layout of lead-out electrodes 36A (third electrode 36), etc.

The insulator 102 is embedded at an upper side inside the first trench 22. Specifically, the insulator 102 is embedded in a recess space that is demarcated by the upper wall surface of the first trench 22, the first insulating film 23, and the first electrode 24 inside the first trench 22. In this embodiment, the insulator 102 is embedded in the first trench 22 such as to traverse a depth position at the bottom portion of the body region 20. That is, the insulator 102 includes a portion which is positioned on the first main surface 3 side and a portion which is positioned on the bottom wall side of the first trench 22 with respect to the bottom portion of the body region 20. The insulator 102 may contain a silicon oxide.

As with the first field trench structure 21A, the second field trench structure 21B has the single electrode structure which includes the first trench 22, the first insulating film 23, the first electrode 24, and the insulator 102. The second field trench structure 21B has the same structure as the first field trench structure 21A except for a difference in length of the first trench 22 and layout of the lead-out electrodes 24A (first electrode 24). A specific description of the second field trench structure 21B will be omitted.

As with the first field trench structure 21A, the third field trench structure 21C has the single electrode structure which includes the first trench 22, the first insulating film 23, the first electrode 24, and the insulator 102. The third field trench structure 21C has the same structure as the first field trench structure 21A except for a difference in length of the first trench 22 and layout of the lead-out electrodes 24A (first electrode 24). A specific description of the third field trench structure 21C will be omitted.

As with the case of the first embodiment, the plurality of first trench gate structures 31A each have the split electrode structure which includes the second trench 32, the second insulating film 33, the third insulating film 34, the second electrode 35, the third electrode 36, and the first intermediate insulating film 37. The second insulating film 33 faces the insulator 102 of the field trench structure 21 in the lateral direction (second direction Y) parallel to the first main surface 3. The third insulating film 34 faces the first insulating film 23 of the field trench structure 21 in the lateral direction (second direction Y) parallel to the first main surface 3.

The second electrode 35 faces the insulator 102 of the field trench structure 21 in the lateral direction (second direction Y) parallel to the first main surface 3. In this embodiment, the second electrode 35 does not face the first electrode 24 of the field trench structure 21 in the lateral direction (second direction Y) parallel to the first main surface 3. As a matter of course, a part of the second electrode 35 may face the first electrode 24 in the lateral direction (second direction Y) parallel to the first main surface 3.

The third electrode 36 faces the first electrode 24 of the field trench structure 21 in the lateral direction (second direction Y) parallel to the first main surface 3. The lead-out electrode 36A of the third electrode 36 faces the lead-out electrode 24A of the field trench structure 21 in the lateral direction (second direction Y) parallel to the first main surface 3. In this embodiment, the third electrode 36 does not face the insulator 102 of the field trench structure 21 in the lateral direction (second direction Y) parallel to the first main surface 3. As a matter of course, a part of the third electrode 36 may face the insulator 102 in the lateral direction (second direction Y) parallel to the first main surface 3. The first intermediate insulating film 37 faces the insulator 102 of the field trench structure 21 in the lateral direction (second direction Y) parallel to the first main surface 3.

As with the plurality of first trench gate structures 31A, the plurality of second trench gate structures 31B each have the split electrode structure which includes the second trench 32, the second insulating film 33, the third insulating film 34, the second electrode 35, the third electrode 36, and the first intermediate insulating film 37. The second trench gate structure 31B has the same structure as the first trench gate structure 31A except for a difference in length of the second trench 32 and layout of the lead-out electrodes 36A (third electrode 36). A specific description of the second trench gate structure 31B will be omitted.

As with the plurality of first trench gate structures 31A, the plurality of third trench gate structures 31C each have the split electrode structure which includes the second trench 32, the second insulating film 33, the third insulating film 34, the second electrode 35, the third electrode 36, and the first intermediate insulating film 37. The third trench gate structure 31C has the same structure as the first trench gate structure 31A except for a difference in length of the second trench 32 and layout of the lead-out electrodes 36A (third electrode 36). A specific description of the third trench gate structure 31C will be omitted.

As with the case of the first embodiment, the first dummy trench gate structure 41A has the dummy split electrode structure (dummy multi-electrode structure) which includes the third trench 42, the fourth insulating film 43, the fifth insulating film 44, the fourth electrode 45, the fifth electrode 46, and the second intermediate insulating film 47.

The fourth insulating film 43 faces the insulator 102 of the field trench structure 21 in the lateral direction (second direction Y) parallel to the first main surface 3. The fourth insulating film 43 faces the second insulating film 33 of the trench gate structure 31 across the field trench structure 21. The fifth insulating film 44 faces the first insulating film 23 of the field trench structure 21 in the lateral direction (second direction Y) parallel to the first main surface 3. The fifth insulating film 44 faces the third insulating film 34 of the trench gate structure 31 across the field trench structure 21.

The fourth electrode 45 faces the insulator 102 of the field trench structure 21 in the lateral direction (second direction Y) parallel to the first main surface 3. The fourth electrode 45 faces the second electrode 35 of the trench gate structure 31 across the field trench structure 21. In this embodiment, the fourth electrode 45 does not face the first electrode 24 of the field trench structure 21 in the lateral direction (second direction Y) parallel to the first main surface 3. As a matter of course, the part of the fourth electrode 45 may face the first electrode 24 in the lateral direction (second direction Y) parallel to the first main surface 3.

The fifth electrode 46 faces the first electrode 24 of the field trench structure 21 in the lateral direction (second direction Y) parallel to the first main surface 3. The fifth electrode 46 faces the third electrode 36 of the trench gate structure 31 across the field trench structure 21. Further, the lead-out electrode 46A of the fifth electrode 46 faces the lead-out electrode 24A of the field trench structure 21 in the lateral direction (second direction Y) parallel to the first main surface 3.

In this embodiment, the fifth electrode 46 does not face the insulator 102 of the field trench structure 21 in the lateral direction (second direction Y) parallel to the first main surface 3. As a matter of course, the fifth electrode 46 may face the insulator 102 in the lateral direction (second direction Y) parallel to the first main surface 3. The second intermediate insulating film 47 faces the insulator 102 of the field trench structure 21 in the lateral direction (second direction Y) parallel to the first main surface 3.

As with the first dummy trench gate structure 41A, the second dummy trench gate structure 41B has the dummy split electrode structure which includes the third trench 42, the fourth insulating film 43, the fifth insulating film 44, the fourth electrode 45, the fifth electrode 46, and the second intermediate insulating film 47. The second dummy trench gate structure 41B has the same structure as the first dummy trench gate structure 41A except for a difference in length of the third trench 42 and layout of the lead-out electrodes 46A (fifth electrode 46). A specific description of the second dummy trench gate structure 41B will be omitted.

As with the first dummy trench gate structure 41A, the third dummy trench gate structure 41C has the dummy split electrode structure which includes the third trench 42, the fourth insulating film 43, the fifth insulating film 44, the fourth electrode 45, the fifth electrode 46, and the second intermediate insulating film 47. The third dummy trench gate structure 41C has the same structure as the first dummy trench gate structure 41A except for the difference in length of the third trench 42 and layout of the lead-out electrodes 46A (fifth electrode 46). A specific description of the third dummy trench gate structure 41C will be omitted.

As with the case of the first embodiment, the source main surface electrode 64 includes the source pad electrode 65. In this embodiment, the source main surface electrode 64 is electrically connected via the plurality of source plug electrodes 57 to the lead-out electrodes 24A (first electrodes 24) of the plurality of field trench structures 21 and the lead-out electrodes 36A (third electrodes 36) of the plurality of trench gate structure 31.

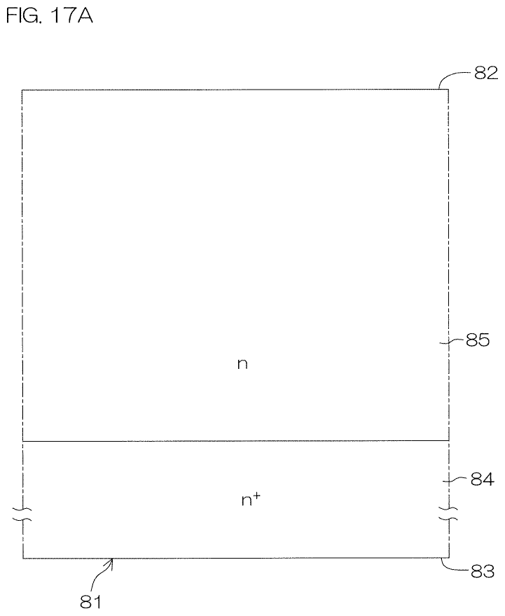

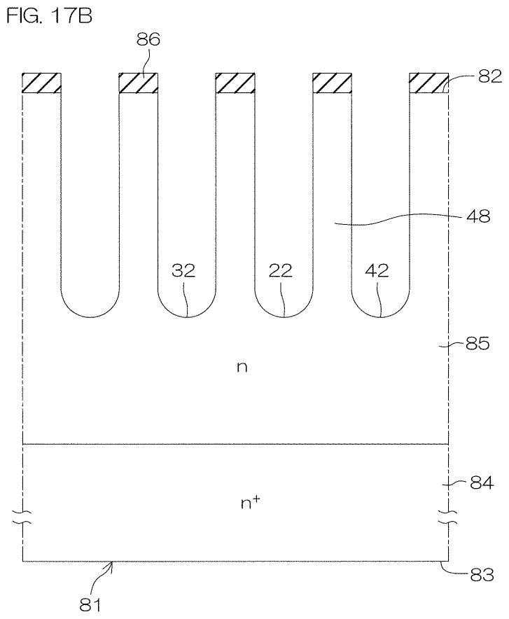

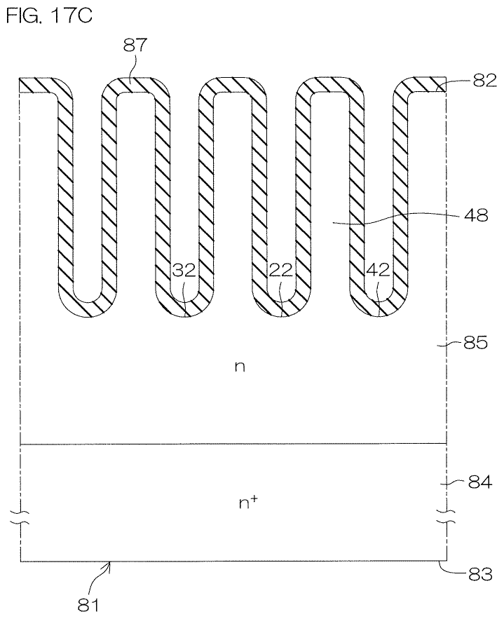

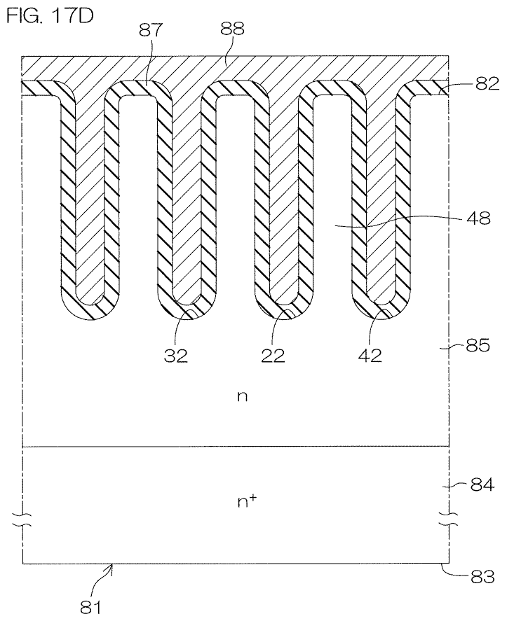

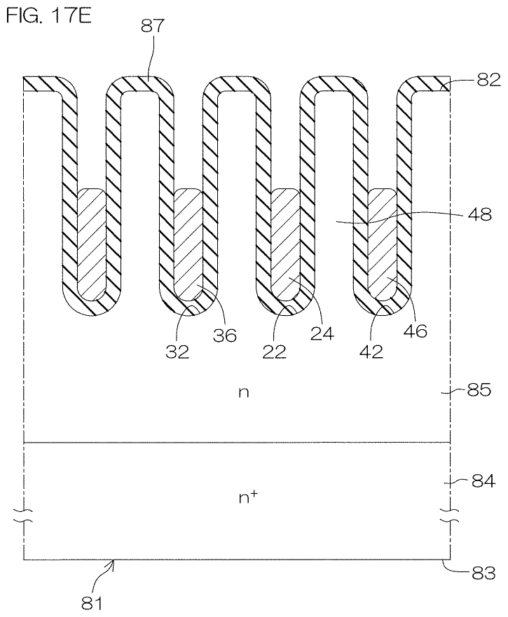

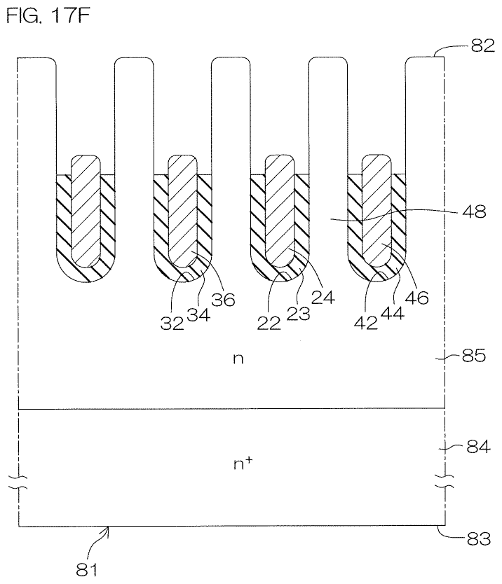

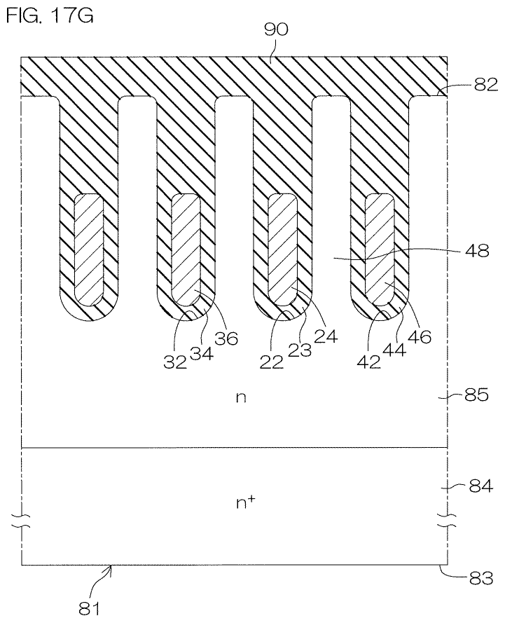

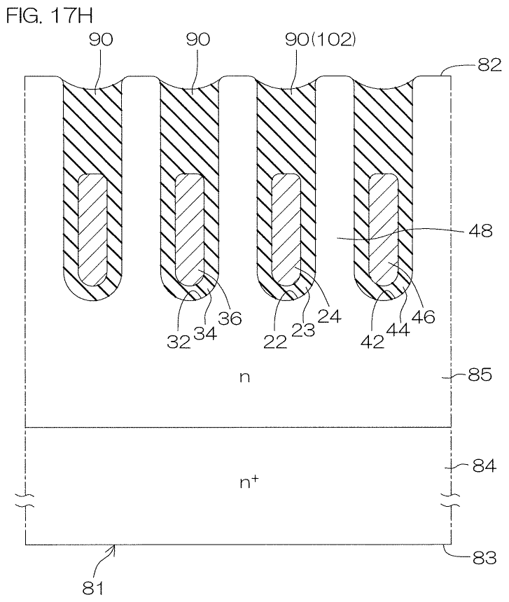

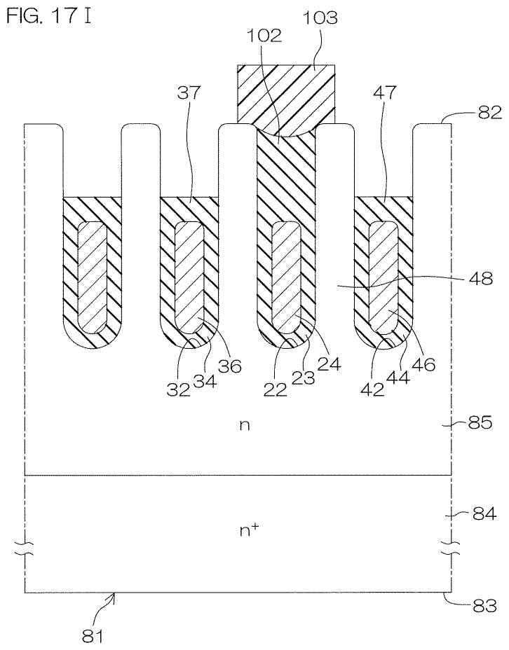

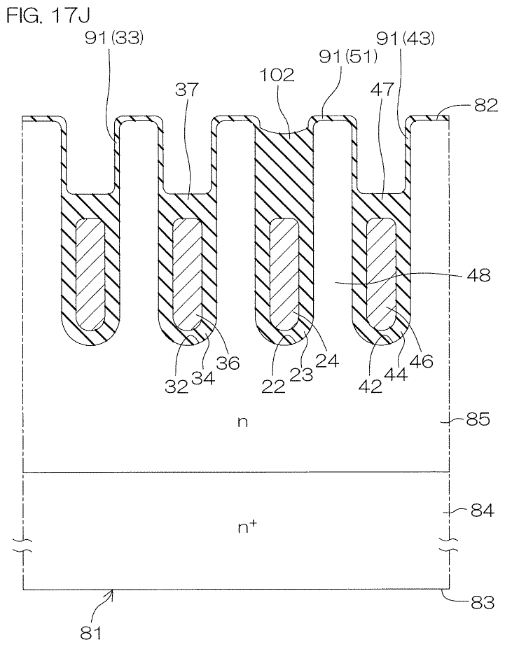

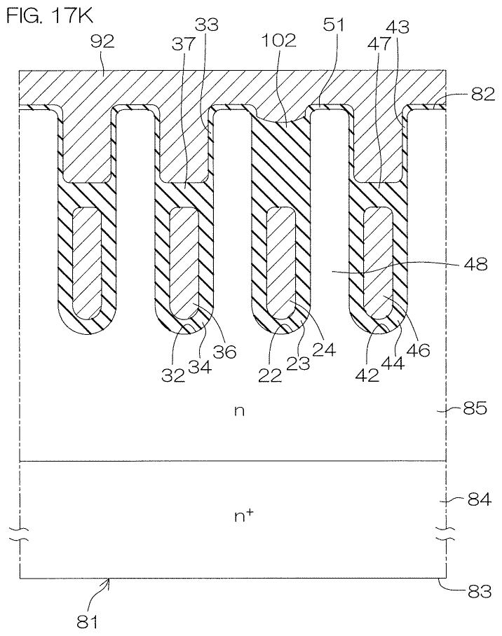

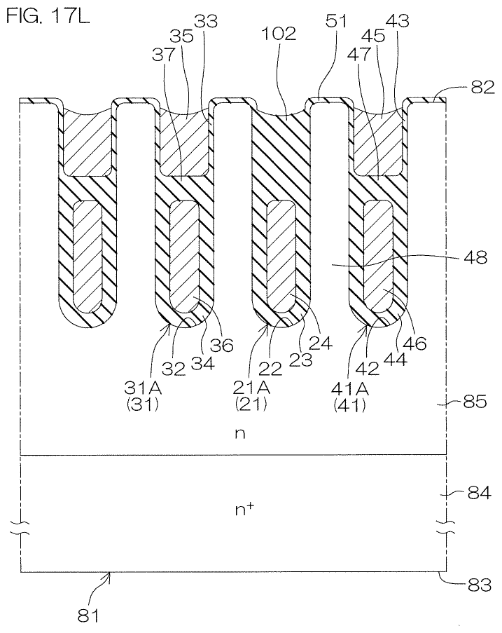

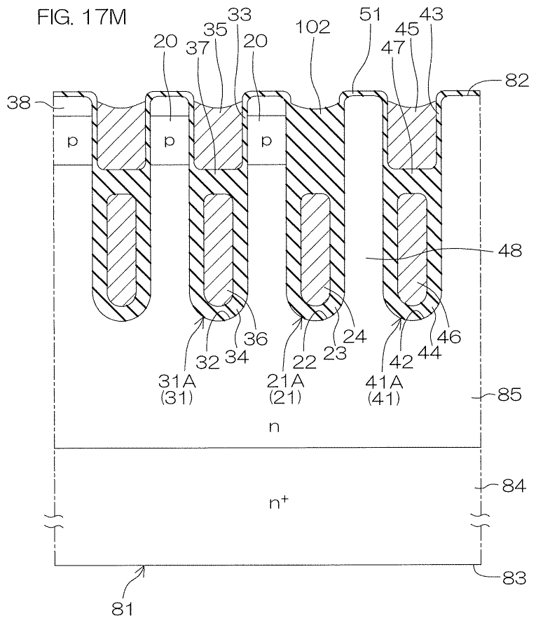

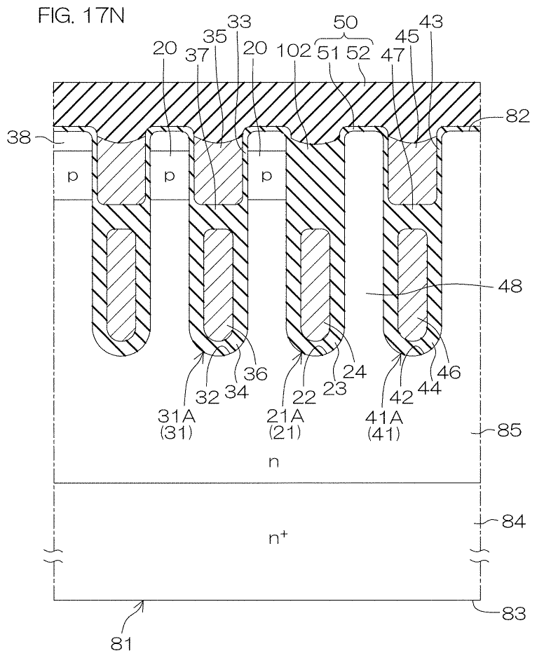

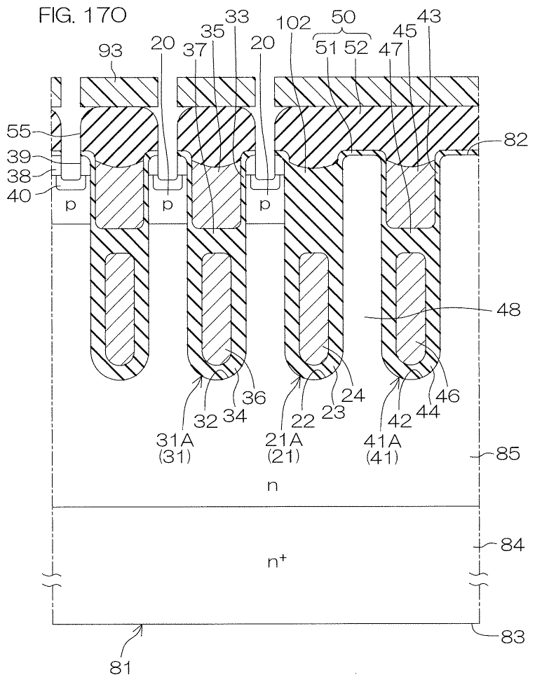

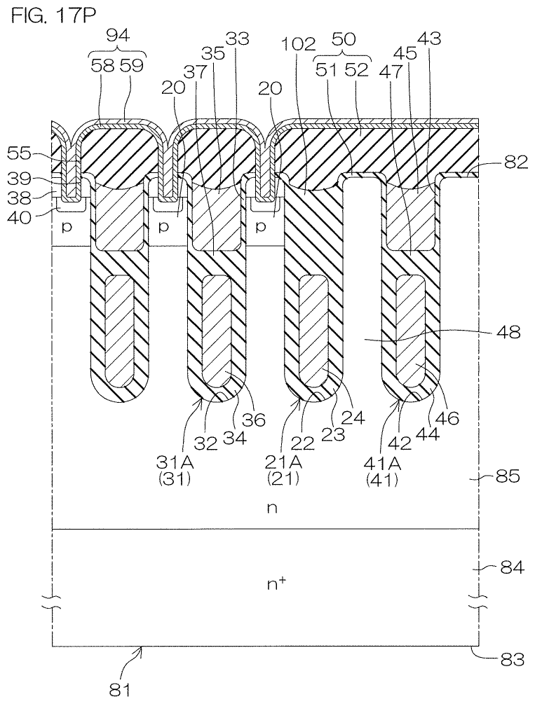

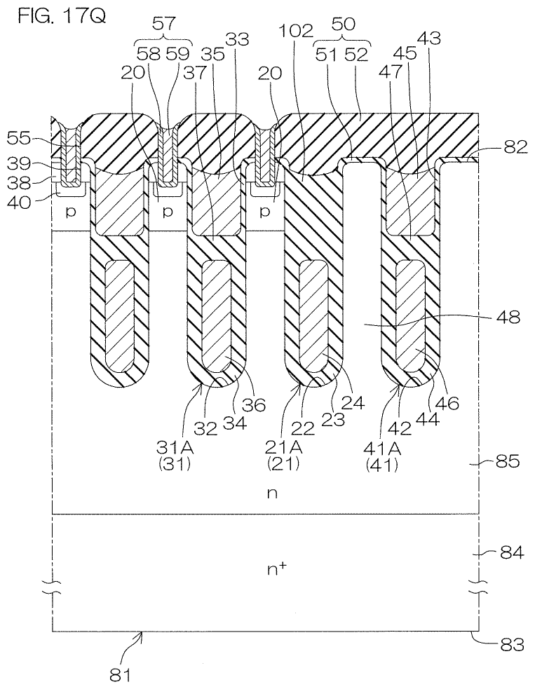

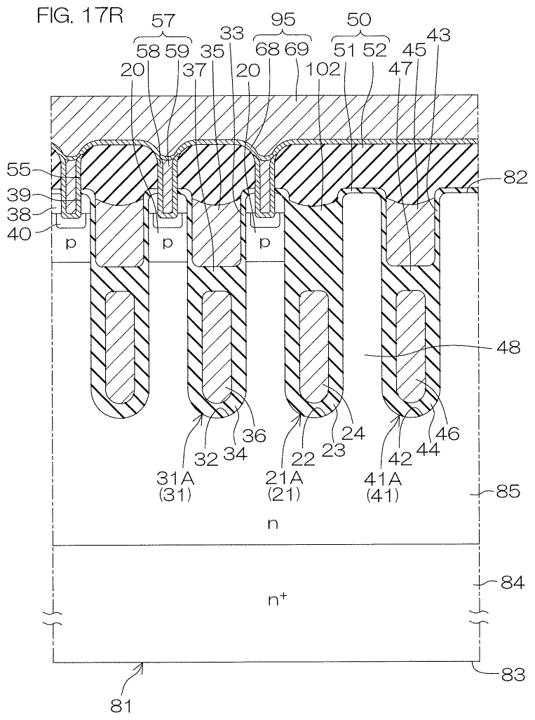

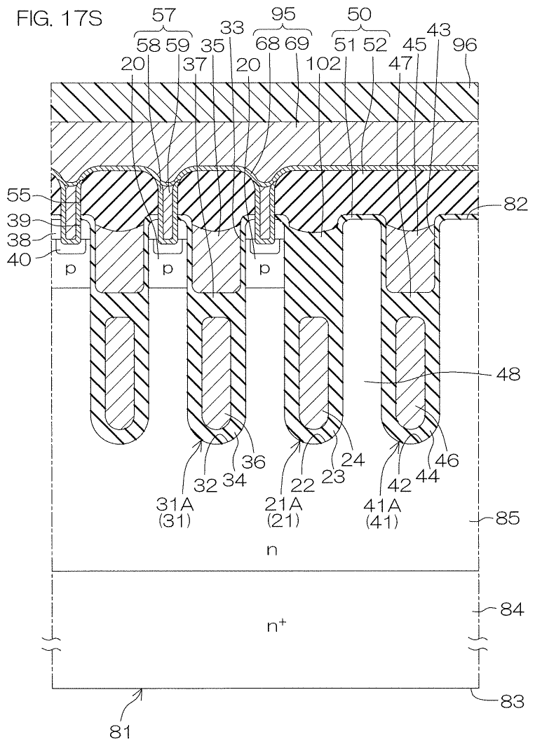

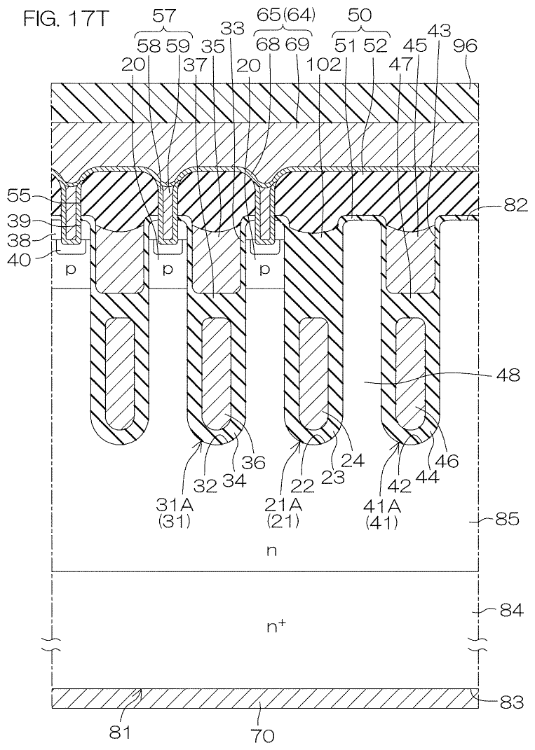

FIG. 17A to FIG. 17T are cross-sectional views for describing one example of a method for manufacturing the semiconductor device 101 shown in FIG. 1. FIG. 17A to FIG. 17T are each a cross-sectional view of a portion corresponding to that of FIG. 13.

With reference to FIG. 17A, an epitaxial wafer 81 which serves as a base of the semiconductor chip 2 is prepared. The epitaxial wafer 81 has a first wafer main surface 82 on one side and a second wafer main surface 83 on the other side. The first wafer main surface 82 and the second wafer main surface 83 respectively correspond to the first main surface 3 and the second main surface 4 of the semiconductor chip 2.

The epitaxial wafer 81 has a laminated structure which includes an n⁺-type semiconductor wafer 84 and an n-type epitaxial layer 85. The epitaxial layer 85 is formed by epitaxial growth of silicon from a main surface of the semiconductor wafer 84. The semiconductor wafer 84 serves as a base of the drain region 6, and the epitaxial layer 85 serves as a base of the drift region 7.

Next, with reference to FIG. 17B, a hard mask 86 having a predetermined pattern is formed on the first wafer main surface 82. The hard mask 86 exposes regions of the first wafer main surface 82 in which the plurality of first trenches 22, the plurality of second trenches 32, and the plurality of third trenches 42 are to be formed and covers the other regions. The hard mask 86 may be formed by a CVD method or an oxidation treatment method (for example, thermal oxidation treatment method). The hard mask 86 may be subjected to patterning by an etching method via a resist mask (not shown).

Next, an unnecessary portion of the first wafer main surface 82 is removed by an etching method via the hard mask 86. The etching method may be a wet etching method and/or a dry etching method. Thereby, the plurality of first trenches 22, the plurality of second trenches 32, and the plurality of third trenches 42 are formed in the first wafer main surface 82. The hard mask 86 is thereafter removed.

Next, with reference to FIG. 17C, a first base insulating film 87 is formed on the first wafer main surface 82. The first base insulating film 87 serves as a base of the first insulating film 23, the third insulating film 34, and the fifth insulating film 44. The first base insulating film 87 is formed as a film along the first wafer main surface 82, wall surfaces of the plurality of first trenches 22, wall surfaces of the plurality of second trenches 32, and wall surfaces of the plurality of third trenches 42. The first base insulating film 87 may be formed by a CVD method and/or an oxidation treatment method (for example, thermal oxidation treatment method).

Next, with reference to FIG. 17D, a first base electrode layer 88 is formed on the first base insulating film 87. The first base electrode layer 88 contains a conductive polysilicon and serves as a base of the first electrode 24, the third electrode 36, and the fifth electrode 46. The first base electrode layer 88 fills the plurality of first trenches 22, the plurality of second trenches 32, and the plurality of third trenches 42 across the first base insulating film 87 and covers the first wafer main surface 82. The first base electrode layer 88 may be formed by a CVD method.

Next, with reference to FIG. 17E, an unnecessary portion of the first base electrode layer 88 is removed by an etching method via a resist mask (not shown). The first base electrode layer 88 is removed up to intermediate portions in the depth direction of the plurality of first trenches 22, the plurality of second trenches 32 and the plurality of third trenches 42. The etching method may be a wet etching method and/or a dry etching method. Thereby, the first electrode 24 (lead-out electrode 24A), the third electrode 36 (lead-out electrode 36A), and the fifth electrode 46 (lead-out electrode 44A) are formed.

Next, with reference to FIG. 17F, an unnecessary portion of the first base insulating film 87 is removed by an etching method via a resist mask (not shown). The first base insulating film 87 is removed until upper wall surfaces of the plurality of first trenches 22, the plurality of second trenches 32, and the plurality of third trenches 42 are exposed. The etching method may be a wet etching method and/or a dry etching method. Thereby, the first insulating film 23, the third insulating film 34, and the fifth insulating film 44 are formed.

Next, with reference to FIG. 17G, a second base insulating film 90 is formed on the first wafer main surface 82. The second base insulating film 90 contains a silicon oxide and serves as a base of the first intermediate insulating film 37, the second intermediate insulating film 47, and the insulator 102. The second base insulating film 90 fills the plurality of second trenches 32 and the plurality of third trenches 42 and covers the first wafer main surface 82. The second base insulating film 90 may be formed by a CVD method.

Next, with reference to FIG. 17H, an unnecessary portion of the second base insulating film 90 is removed by an etching method until the first wafer main surface 82 is exposed. The etching method may be a wet etching method and/or a dry etching method.

Next, with reference to FIG. 17I, a resist mask 103 having a predetermined pattern is formed on the first wafer main surface 82. The resist mask 103 covers the plurality of first trenches 22 and selectively exposes the plurality of second trenches 32 and the plurality of third trenches 42. Next, an unnecessary portion of the second base insulating film 90 is removed by an etching method via the resist mask 103.

The etching method may be a wet etching method and/or a dry etching method. Thereby, the first intermediate insulating film 37, the second intermediate insulating film 47, and the insulator 102 are formed. The thickness of the first intermediate portion 37A of the first intermediate insulating film 37 and the thickness of the second intermediate portion 47A of the second intermediate insulating film 47 are each adjusted to an arbitrary value by a layout of the resist mask 103. The resist mask 103 is thereafter removed.

Next, with reference to FIG. 17J, a third base insulating film 91 is formed as a film along the first wafer main surface 82, the wall surfaces of the plurality of second trenches 32, and the wall surfaces of the plurality of third trenches 42. The third base insulating film 91 serves as a base of the second insulating film 33, the fourth insulating film 43, and the first main surface insulating film 51. The third base insulating film 91 is also formed on an outer surface of the first electrode 24 (lead-out electrode 24A), an outer surface of the third electrode 36 (lead-out electrode 36A), and an outer surface of the fifth electrode 46 (lead-out electrode 44A). The third base insulating film 91 may be formed by a CVD method and/or an oxidation treatment method (for example, thermal oxidation treatment method).

Next, with reference to FIG. 17K, a second base electrode layer 92 is formed on the third base insulating film 91. The second base electrode layer 92 contains a conductive polysilicon and serves as a base of the second electrode 35 and the fourth electrode 45. The second base electrode layer 92 fills the plurality of second trenches 32 and the plurality of third trenches 42 across the third base insulating film 91 and covers the first wafer main surface 82. The second base electrode layer 92 may be formed by a CVD method.

Next, with reference to FIG. 17L, an unnecessary portion of the second base electrode layer 92 is removed by an etching method until the first main surface insulating film 51 is exposed. The etching method may be a wet etching method and/or a dry etching method. Thereby, the second electrode 35 and the fourth electrode 45 are formed. Further, the plurality of field trench structures 21, the plurality of trench gate structures 31, and the plurality of dummy trench gate structures 41 are formed.

Next, with reference to FIG. 17M, a body region 20 is formed in a surface layer portion of the first wafer main surface 82. The body region 20 is formed by an ion implantation method via an ion implantation mask (not shown) through introduction of a p-type impurity into the surface layer portion of the first wafer main surface 82. Specifically, the p-type impurity of the body region 20 is introduced into the surface layer portion of the first wafer main surface 82 from the first wafer main surface 82 and a side wall of the second trench 32.

Further, a source region 38 is formed in the surface layer portion of the first wafer main surface 82. The source region 38 is formed by an ion implantation method via an ion implantation mask (not shown) through introduction of an n-type impurity into the surface layer portion of the first wafer main surface 82. Specifically, the n-type impurity source region 38 is introduced into the surface layer portion of the first wafer main surface 82 from the first wafer main surface 82 and the side wall of the second trench 32. The source region 38 may be formed after a forming step of the body region 20 or may be formed prior to the forming step of the body region 20.

Next, with reference to FIG. 17N, a second main surface insulating film 52 is formed on a first main surface insulating film 51. The second main surface insulating film 52 collectively covers the plurality of field trench structures 21, the plurality of trench gate structures 31, and the plurality of dummy trench gate structures 41. The second main surface insulating film 52 contains a silicon oxide. The second main surface insulating film 52 may be formed by a CVD method. Thereby, a main surface insulating film 50 that includes the first main surface insulating film 51 and the second main surface insulating film 52 is formed.

Next, with reference to FIG. 17O, a resist mask 93 having a predetermined pattern is formed on the main surface insulating film 50. The resist mask 93 exposes regions of the main surface insulating film 50 in which a plurality of gate openings 53, a plurality of source openings 54, and a plurality of source contact openings 55 are to be formed and covers the other regions.

Next, an unnecessary portion of the main surface insulating film 50 is removed by an etching method via the resist mask 93. The etching method may be a wet etching method and/or a dry etching method. Thereby, the plurality of gate openings 53, the plurality of source openings 54 and the plurality of source contact openings 55 are formed in the main surface insulating film 50.

Next, portions of the first wafer main surface 82 which are exposed from the plurality of source contact openings 55 are removed by an etching method via the plurality of source contact openings 55. The etching method may be a wet etching method and/or a dry etching method. Thereby, a plurality of source contact holes 39 which are communicatively connected to the plurality of source contact openings 55 are formed in the first wafer main surface 82. The resist mask 93 may be removed after formation of the source contact holes 39 or may be removed after formation of the source contact openings 55.

Next, a contact region 40 is formed in a region of the surface layer portion of the body region 20 along a bottom wall of the source contact hole 39. The contact region 40 is formed by an ion implantation method via an ion implantation mask (not shown) through introduction of a p-type impurity into the bottom wall of the source contact hole 39.

Next, with reference to FIG. 17P, a third base electrode layer 94 is formed on the main surface insulating film 50. The third base electrode layer 94 serves as a base of a plurality of gate plug electrodes 56 and a plurality of source plug electrodes 57. The third base electrode layer 94 includes a barrier electrode 58 and a main electrode 59 laminated in this order from the main surface insulating film 50 side. The barrier electrode 58 includes at least one of a Ti layer and a TiN layer. The main electrode 59 contains tungsten. The barrier electrode 58 and the main electrode 59 may each be formed by a sputtering method and/or a vapor deposition method.

Next, with reference to FIG. 17Q, an unnecessary portion of the third base electrode layer 94 is removed by an etching method until the main surface insulating film 50 is exposed. The etching method may be a wet etching method and/or a dry etching method. Thereby, the plurality of gate plug electrodes 56 and the plurality of source plug electrodes 57 are formed.

Next, with reference to FIG. 17R, a fourth base electrode layer 95 is formed on the main surface insulating film 50. The fourth base electrode layer 95 serves as a base of a gate main surface electrode 61 and a source main surface electrode 64. The fourth base electrode layer 95 includes a barrier electrode 68 and a main electrode 69 laminated in this order from the main surface insulating film 50 side. The barrier electrode 68 includes at least one of a Ti layer and a TiN layer. The main electrode 69 includes at least one of a pure Cu layer, a pure Al layer, an AlSi alloy layer, an AlCu alloy layer, and an AlSiCu alloy layer. The barrier electrode 68 and the main electrode 69 may each be formed by a sputtering method and/or a vapor deposition method.

Next, with reference to FIG. 17S, a resist mask 96 having a predetermined pattern is formed on the fourth base electrode layer 95. The resist mask 96 covers regions of the fourth base electrode layer 95 in which the gate main surface electrode 61 and the source main surface electrode 64 are to be formed and exposes the other regions. Next, an unnecessary portion of the fourth base electrode layer 95 is removed by an etching method via the resist mask 96. The etching method may be a wet etching method and/or a dry etching method. Thereby, the gate main surface electrode 61 and the source main surface electrode 64 are formed.

Next, with reference to FIG. 17T, a drain electrode 70 is formed on the second wafer main surface 83. The drain electrode 70 includes at least one of a Ti layer, an Ni layer, a Pd layer, an Au layer, and an Ag layer. The drain electrode 70 may be formed by a sputtering method and/or a vapor deposition method. Thereafter, the epitaxial wafer 81 is selectively cut and the plurality of semiconductor devices 101 are cut out. The semiconductor device 101 is manufactured through the steps including the above.

As described above, the semiconductor device 101 which includes the insulator 102 embedded at the upper side inside the first trench 22 is also able to provide the same effects as those described for the semiconductor device 1.

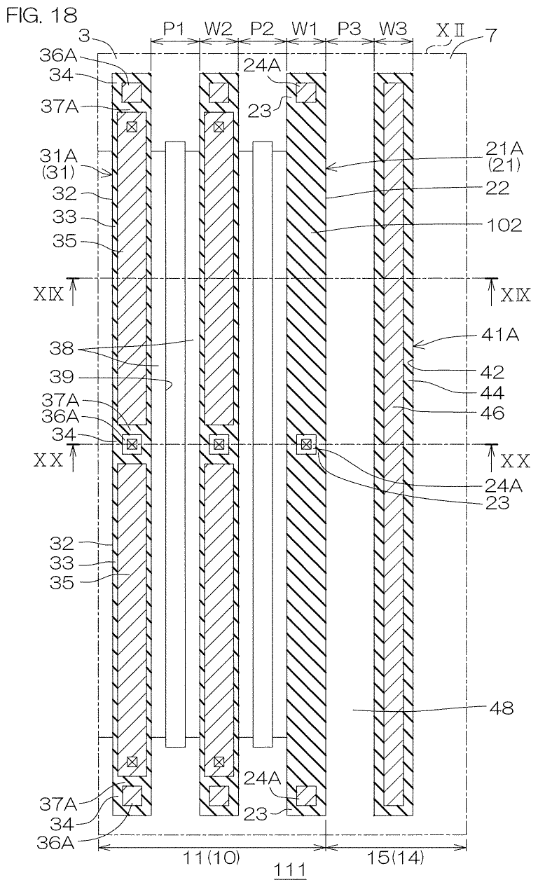

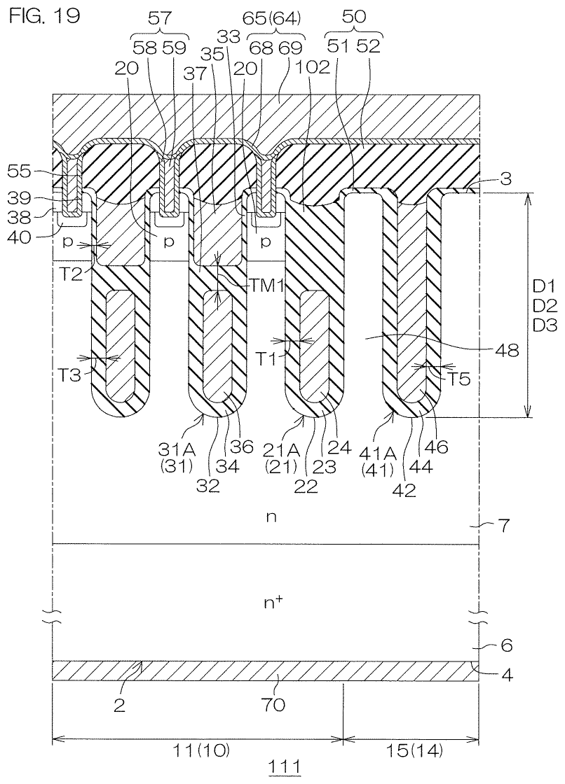

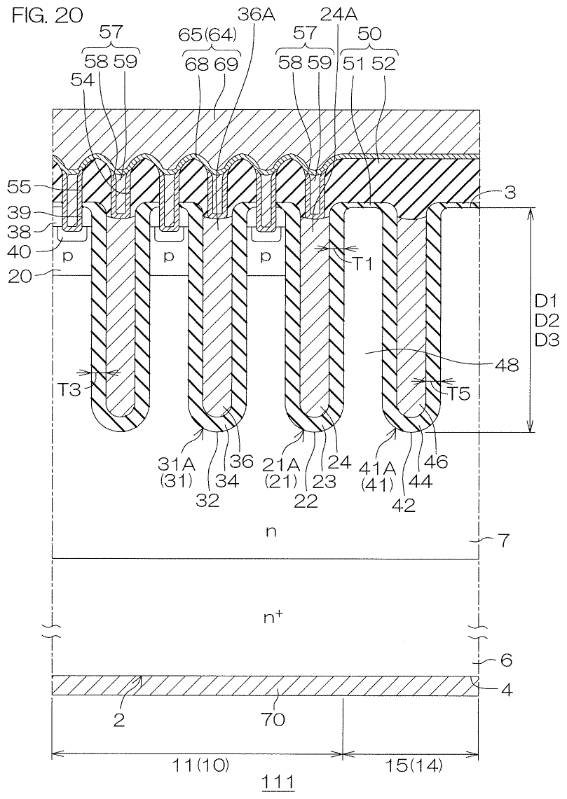

FIG. 18 is a drawing corresponding to FIG. 12 and an enlarged view showing a structure of a first main surface 3 of a semiconductor chip 2 of a semiconductor device 111 according to the third embodiment of the present invention. FIG. 19 is a cross-sectional view along line XIX-XIX shown in FIG. 18. The FIG. 20 is a cross-sectional view along line XX-XX shown in FIG. 18. The semiconductor device 111 has a mode in which the structure of the semiconductor device 101 according to the second embodiment is modified. Hereinafter, the same reference sign is given to a structure corresponding to the structure described for the semiconductor device 101, and a description thereof will be omitted.

With reference to FIG. 18 to FIG. 20, in the semiconductor device 111, the trench gate structure 31 is different from the field trench structure 21 in internal structure. Further, the dummy trench gate structure 41 is different from the field trench structure 21 in internal structure. Further, the dummy trench gate structure 41 is different from the trench gate structure 31 in internal structure.

Specifically, the field trench structure 21 has a single electrode structure which includes a single electrode. Further, the trench gate structure 31 has a multi-electrode structure which includes multiple electrodes divided and arranged in an up/down direction. Still further, the dummy trench gate structure 41 has a dummy single electrode structure which includes a single electrode. The field trench structure 21 and the trench gate structure 31 are each formed in the same mode as with the structure according to the second embodiment.

In this embodiment, the first dummy trench gate structure 41A has a dummy single electrode structure that includes the third trench 42, the fifth insulating film 44, and the fifth electrode 46 but does not include the fourth insulating film 43, the fourth electrode 45, or the second intermediate insulating film 47, which is different from the structure according to the second embodiment. That is, the fifth insulating film 44 forms a single dummy insulating film which covers the wall surface of the third trench 42, and the fifth electrode 46 forms the single dummy electrode that is embedded in the third trench 42 across the dummy insulating film. The fifth electrode 46 can be regarded as having the structure which includes the single lead-out electrode 46A that is led out in an entire area on the opening side of the third trench 42 across the fifth insulating film 44 in the structure according to the second embodiment.

Specifically, the fifth insulating film 44 covers the upper wall surface and the lower wall surface of the third trench 42. In this embodiment, the fifth insulating film 44 covers as a film an entire area of the wall surface of the third trench 42. The fifth insulating film 44 faces the first insulating film 23, the first electrode 24 (lead-out electrode 24A), and the insulator 104 of the field trench structure 21 in the lateral direction (second direction Y) parallel to the first main surface 3. Further, the fifth insulating film 44 faces the second insulating film 33, the third insulating film 34, the second electrode 35, the third electrode 36 (lead-out electrode 36A), and the first intermediate insulating film 37 of the trench gate structure 31 across the field trench structure 21.

Specifically, the fifth electrode 46 is embedded at the opening side (upper wall surface side) and at the bottom side (lower wall surface side) of the third trench 42 across the fifth insulating film 44. In this embodiment, the fifth electrode 46 faces the first insulating film 23, the first electrode 24 (lead-out electrode 24A), and the insulator 104 of the field trench structure 21 in the lateral direction (second direction Y) parallel to the first main surface 3. Further, the fifth electrode 46 faces the second insulating film 33, the third insulating film 34, the second electrode 35, the third electrode 36 (lead-out electrode 36A), and the first intermediate insulating film 37 of the trench gate structure 31 across the field trench structure 21.

As with the first dummy trench gate structure 41A, the second dummy trench gate structure 41B has the dummy single electrode structure which includes the third trench 42, the fifth insulating film 44, and the fifth electrode 46. The second dummy trench gate structure 41B has the same structure as the first dummy trench gate structure 41A except for a difference in length of the third trench 42. A specific description of the second dummy trench gate structure 41B will be omitted.

As with the first dummy trench gate structure 41A, the third dummy trench gate structure 41C has the dummy single electrode structure which includes the third trench 42, the fifth insulating film 44, and the fifth electrode 46. The third dummy trench gate structure 41C has the same structure as the first dummy trench gate structure 41A except for a difference in length of the third trench 42. A specific description of the third dummy trench gate structure 41C will be omitted.

In this embodiment, the main surface insulating film 50 covers an entire area of the plurality of dummy trench gate structures 41 (exposed portions of the plurality of fifth electrodes 46) to insulate and separate the plurality of dummy trench gate structures 41 from outside. That is, the main surface insulating film 50 isolates, together with the fifth insulating film 44, the plurality of fifth electrodes 46 in an electrically floating state.

As described above, the semiconductor device 111 is also able to provide the same effects as those described for the semiconductor device 1.

The present invention can be implemented in still other embodiments.

In each of the aforementioned embodiments, a description has been given of an example in which the body region 20 is not formed at the surface layer portion of the first main surface 3 in the mesa portion 48. However, the body region 20 may be formed at the surface layer portion of the first main surface 3 in the mesa portion 48. In this case, the fourth insulating film 43 of the dummy trench gate structure 41 may be in contact with the body region 20 in the same mode as the second insulating film 33 of the trench gate structure 31. Further, the fourth electrode 45 of the dummy trench gate structure 41 may face the body region 20 across the fourth insulating film 43 in the same mode as the second electrode 35 of the trench gate structure 31.

In each of the aforementioned embodiments, a description has been given of an example in which the third electrode 36 of the trench gate structure 31 is formed as a field electrode and a source potential (for example, ground potential) as a reference potential is to be applied to the third electrode 36. However, the third electrode 36 may be formed as a gate electrode and the gate potential as a control potential may be applied to the third electrode 36. That is, the third electrode 36 may be fixed to the same potential as the second electrode 35 and may also be fixed to a potential different from that of the first electrode 24. In this case, the gate main surface electrode 61 (gate finger electrode 63) is electrically connected via the gate plug electrode 56 to the lead-out electrode 36A of the third electrode 36.

In each of the aforementioned embodiments, a description has been given of an example in which the source main surface electrode 64 is not connected to the plurality of lead-out electrodes 36A or the plurality of lead-out electrodes 46A which are positioned at both ends. However, the source main surface electrode 64 may be connected via the plurality of source plug electrodes 57 to the plurality of lead-out electrodes 36A and the plurality of lead-out electrodes 46A which are positioned at both ends. In this case, the source main surface electrode 64 may include a source finger electrode which is led out as a line from the source pad electrode 65 such as to be connected to the plurality of lead-out electrodes 36A and the plurality of lead-out electrodes 46A which are positioned at both ends.

In each of the aforementioned embodiments, a description has been given of an example in which the “first conductive type” is an “n-type” and the “second conductive type” is a p-type. However, the “first conductive type” may be a “p-type” and the “second conductive type” may be an “n-type.” A specific configuration of the above case can be obtained by replacing the “n-type region” with the “p-type region” and replacing the “n-type region” with the “p-type region”) in the aforementioned description and the attached drawings.

Examples of features extracted from this description and drawings are indicated below. The following [A1] to [A20] and [B1] to [B20] are to provide a semiconductor device capable of suppressing a crystal defect of a semiconductor chip. Although alphanumeric characters within parentheses in the following express corresponding components, etc., in the embodiments described above, these are not meant to limit the scopes of respective clauses to the embodiments.

[A1] A semiconductor device comprising: a semiconductor chip (2) which has a main surface (3); a first groove (22) which is formed in the main surface (3) and demarcates the main surface (3) into a first region (10) and a second region (14); a first insulating film (23) which is formed on a wall surface of the first groove (22); a second groove (32) which is formed in the main surface (3) of the first region (10) at an interval from the first groove (22); a second insulating film (33) which covers an upper wall surface of the second groove (32) and is thinner than the first insulating film (23); a third insulating film (34) which covers a lower wall surface of the second groove (32) and is thicker than the second insulating film (33); a third groove (42) which is formed in the main surface (3) of the second region (14) at an interval from the first groove (22); a fourth insulating film (43) which covers an upper wall surface of the third groove (42) and is thinner than the first insulating film (23); and a fifth insulating film (44) which covers a lower wall surface of the third groove (42) and is thicker than the fourth insulating film (43).

[A2] The semiconductor device according to A1, wherein the first region (10) is an active region (10) and the second region (14) is a non-active region (14) outside the active region (10).

[A3] The semiconductor device according to A1 or A2 further comprising: a first electrode (24) which is embedded in the first groove (22) across the first insulating film (23); a second electrode (35) which is embedded at an upper side of the second groove (32) across the second insulating film (33); a third electrode (36) which is embedded at a lower side of the second groove (32) across the third insulating film (34); a fourth electrode (45) which is embedded at an upper side of the third groove (42) across the fourth insulating film (43); and a fifth electrode (46) which is embedded at a lower side of the third groove (42) across the fifth insulating film (44).

[A4] The semiconductor device according to A3, wherein the fourth electrode (45) in an electrically floating state is embedded at the upper side of the third groove (42), and the fifth electrode (46) in an electrically floating state is embedded at the lower side of the third groove (42).

[A5] The semiconductor device according to A3 or A4 further comprising: a first intermediate insulating film (37) which is interposed between the second electrode (35) and the third electrode (36); and a second intermediate insulating film (47) which is interposed between the fourth electrode (45) and the fifth electrode (46).

[A6] The semiconductor device according to A5, wherein the first intermediate insulating film (37) is thicker than the second insulating film (33), and the second intermediate insulating film (47) is thicker than the fourth insulating film (43).

[A7] The semiconductor device according to any one of A3 to A6, wherein a reference potential is to be applied to the first electrode (24), a control potential is to be applied to the second electrode (35), and the reference potential or the control potential is to be applied to the third electrode (36).

[A8] The semiconductor device according to A7, wherein the reference potential is to be applied to the third electrode (36).

[A9] The semiconductor device according to any one of A3 to A8, wherein the third electrode (36) includes one or a plurality of first lead-out electrodes (36A) led out to an opening side of the second groove (32) across the third insulating film (34), and the fifth electrode (46) includes one or a plurality of second lead-out electrodes (46A) led out to an opening side of the third groove (42) across the fifth insulating film (44).

[A10] The semiconductor device according to A9, wherein the second lead-out electrode (46A) faces the first lead-out electrode (36A) across the first groove (22).

[A11] The semiconductor device according to any one of A1 to A10 further comprising: a body region (20) which is formed in a surface layer portion of the main surface (3); wherein the second groove (32) penetrates through the body region (20).

[A12] The semiconductor device according to A11, wherein the third groove (42) demarcates a mesa portion (48) which is constituted of a part of the semiconductor chip (2) with the first groove (22), and the body region (20) is not formed in the mesa portion (48).

[A13] The semiconductor device according to A11 or A12 further comprising: a source region (38) which is formed in a region along the second groove (32) in a surface layer portion of the body region (20).

[A14] The semiconductor device according to any one of A1 to A13, wherein the first groove (22) is formed in a band shape in a plan view, the second groove (32) is formed in a band shape extending in parallel with the first groove (22) in a plan view, and the third groove (42) is formed in a band shape extending in parallel with the first groove (22) in a plan view.

[A15] The semiconductor device according to any one of A1 to A14 further comprising: a plurality of the second grooves (32).

[A16] The semiconductor device according to A15, wherein the plurality of second grooves (32) are formed at an interval of not less than 0.1 μm and not more than 2 μm.

[A17] The semiconductor device according to any one of A1 to A16, wherein the second groove (32) is formed at an interval (P2) of not less than 0.1 μm and not more than 2 μm from the first groove (22), and the third groove (42) is formed at an interval (P3) of not less than 0.1 μm and not more than 2 μm from the first groove (22).

[A18] The semiconductor device according to any one of A1 to A17 further comprising: a main surface insulating film (50) which is formed on the main surface (3) and insulates the third groove (42) from outside.

[A19] The semiconductor device according to any one of A1 to A18, wherein the first groove (22) has a width (W1) which is not less than 0.5 μm and not more than 3 μm, the second groove (32) has a width (W2) which is not less than 0.5 μm and not more than 3 μm, and the third groove (42) has a width (W3) which is not less than 0.5 μm and not more than 3 μm.

[A20] The semiconductor device according to any one of A1 to A19, wherein the first groove (22) has a depth (D1) which is not less than 1 μm and not more than 10 μm, the second groove (32) has a depth (D2) which is not less than 1 μm and not more than 10 μm, and the third groove (42) has a depth (D3) which is not less than 1 μm and not more than 10 μm.

[B1] A semiconductor device comprising: a semiconductor chip (2) which has a main surface (3); a field trench structure (21) which is formed in the main surface (3) and demarcates an active region (10) and a non-active region (11) in the main surface (3); a trench gate structure (31) which is formed in the active region (10) at an interval from the field trench structure (21) and faces the field trench structure (21); and a dummy trench structure (41) which is formed in the non-active region (11) at an interval from the field trench structure (21) and faces the trench gate structure (31) across the field trench structure (21).

[B2] The semiconductor device according to B1, wherein the dummy trench structure (41) is electrically disconnected from the trench gate structure (31).

[B3] The semiconductor device according to B1 or B2, wherein the dummy trench structure (41) is electrically disconnected from the field trench structure (21).

[B4] the semiconductor device according to any one of B1 to B3, wherein the dummy trench structure (41) is formed in an electrically floating state.

[B5] The semiconductor device according to any one of B1 to B4, wherein the trench gate structure (31) has an internal structure different from that of the field trench structure (21).

[B6] The semiconductor device according to any one of B1 to B5, wherein the dummy trench structure (41) has an internal structure different from that of the field trench structure (21).

[B7] The semiconductor device according to any one of B1 to B6, wherein the dummy trench structure (41) has an internal structure different from that of the trench gate structure (31).

[B8] The semiconductor device according to any one of B1 to B7, wherein the field trench structure (21) has a single electrode structure which includes a single electrode, the trench gate structure (31) has a multi-electrode structure which includes multiple electrodes which are divided and arranged in an up/down direction, and the dummy trench structure (41) has a single electrode structure which includes a single electrode.

[B9] The semiconductor device according to B8, wherein the field trench structure (21) includes a field trench (22) which is formed in the main surface (3), a field electrode (24) which is embedded at a bottom wall side of the field trench (22), and a field insulator (102) which is embedded at an opening side of the field trench (22).

[B10] The semiconductor device according to B9, wherein the trench gate structure (31) includes a gate trench (32) formed in the main surface (3), an upper electrode (35) embedded at an opening side of the gate trench (32), and a lower electrode (36) embedded at a bottom wall side of the gate trench (32), the upper electrode (35) faces the field insulator (102) across a part of the semiconductor chip (2), and the lower electrode (36) faces the field electrode (24) across a part of the semiconductor chip (2).

[B11] The semiconductor device according to B10, wherein the field trench structure (21) includes a first lead-out electrode (24A) which is led out to an opening side of the field trench (22) from the field electrode (24), and the trench gate structure (31) includes a second lead-out electrode (36A) which is led out to an opening side of the gate trench (32) from the lower electrode (36).

[B12] The semiconductor device according to B10 or B11, wherein the trench gate structure (31) includes an intermediate insulating film (37) which is interposed between the upper electrode (35) and the lower electrode (36), and the intermediate insulating film (37) faces the field insulator (102) across a part of the semiconductor chip (2).

[B13] The semiconductor device according to B11 or B12, wherein a gate potential is to be applied to the upper electrode (35), and a potential that is the same as that of the field electrode (24) is to be applied to the lower electrode (36).

[B14] The semiconductor device according to any one of B9 to B13, wherein the dummy trench structure (41) includes a dummy trench (42) which is formed in the main surface (3) and a dummy electrode (46) which is embedded in the dummy trench (42), and the dummy electrode (46) faces the field electrode (24) and the field insulator (102) across a part of the semiconductor chip (2).

[B15] The semiconductor device according to any one of B1 to B7, wherein the field trench structure (21) includes a field trench (22) which is formed in the main surface (3) and a field insulating film (23) which covers a wall surface of the field trench (22), the trench gate structure (31) includes a gate trench (32) which is formed in the main surface (3), an upper insulating film (33) which covers an upper wall surface of the gate trench (32), and a lower insulating film (34) which covers a lower wall surface of the gate trench (32), the dummy trench structure (41) includes a dummy trench (42) which is formed in the main surface (3) and a dummy insulating film (44) which covers a wall surface of the dummy trench (42), the upper insulating film (33) is thinner than the field insulating film (23), the lower insulating film (34) is thicker than the upper insulating film (33), and the dummy insulating film (44) is thicker than the upper insulating film (33).

[B16] The semiconductor device according to any one of B1 to B15, wherein the field trench structure (21) is formed in a band shape extending in one direction in a plan view, the trench gate structure (31) is formed in a band shape extending in parallel with the field trench structure (21) in a plan view, and the dummy trench structure (41) is formed in a band shape extending in parallel with the field trench structure (21) in a plan view.

[B17] The semiconductor device according to any one of B1 to B16, wherein the trench gate structure (31) is formed with a first interval (P2) kept from the field trench structure (21), and the dummy trench structure (41) is formed with a second interval (P3) which is substantially equal to the first interval (P2) kept from the field trench structure (21).

[B18] The semiconductor device according to any one of B1 to B17, wherein the trench gate structure (31) is formed with a depth (D1≈D2) which is substantially equal to that of the field trench structure (21), and the dummy trench structure (41) is formed with a depth (D1≈D3) which is substantially equal to that of the field trench structure (21).

[B19] The semiconductor device according to any one of B1 to B18, wherein a plurality of the trench gate structures (31) are formed in the active region (10) at an interval from the field trench structure (21), and the single dummy trench structure (41) is formed in the non-active region (11) at an interval from the field trench structure (21).

[B20] The semiconductor device according to any one of B1 to B19 further comprising: a body region (20) which is formed in a surface layer portion of the main surface (3); wherein the field trench structure (21) penetrates through the body region (20), the trench gate structure (31) penetrates through the body region (20), and the dummy trench structure (41) does not penetrate through the body region (20).

While the embodiments of the present invention have been described in detail, these are merely specific examples used to clarify the technical contents of the present invention, and the present invention should not be interpreted as being limited to these specific examples and the scope of the present invention is limited only by the appended claims.

### REFERENCE SIGNS LIST

1 semiconductor device
2 semiconductor chip
3 first main surface
10 active region (first region)
14 non-active region (second region)
20 body region
22 first trench (first groove)
23 first insulating film
24 first electrode
32 second trench (second groove)
33 second insulating film
34 third insulating film
35 second electrode
36 third electrode
37 first intermediate insulating film
38 source region
42 third trench (third groove)
43 fourth insulating film
44 fifth insulating film
45 fourth electrode
46 fifth electrode
47 second intermediate insulating film
48 mesa portion
50 main surface insulating film
101 semiconductor device

1. A semiconductor device comprising:
a semiconductor chip which has a main surface;
a first groove which is formed in the main surface and demarcates the main surface into a first region and a second region;
a first insulating film which is formed on a wall surface of the first groove;
a second groove which is formed in the main surface of the first region at an interval from the first groove;
a second insulating film which covers an upper wall surface of the second groove and is thinner than the first insulating film;
a third insulating film which covers a lower wall surface of the second groove and is thicker than the second insulating film;
a third groove which is formed in the main surface of the second region at an interval from the first groove;
a fourth insulating film which covers an upper wall surface of the third groove and is thinner than the first insulating film; and
a fifth insulating film which covers a lower wall surface of the third groove and is thicker than the fourth insulating film.

2. The semiconductor device according to claim 1, wherein
the first region is an active region, and
the second region is a non-active region outside the active region.

3. The semiconductor device according to claim 1, further comprising:
a first electrode which is embedded in the first groove across the first insulating film;
a second electrode which is embedded at an upper side of the second groove across the second insulating film;
a third electrode which is embedded at a lower side of the second groove across the third insulating film;
a fourth electrode which is embedded at an upper side of the third groove across the fourth insulating film; and
a fifth electrode which is embedded at a lower side of the third groove across the fifth insulating film.

4. The semiconductor device according to claim 3, wherein
the fourth electrode in an electrically floating state is embedded at the upper side of the third groove, and
the fifth electrode in an electrically floating state is embedded at the lower side of the third groove.

5. The semiconductor device according to claim 3, further comprising:
a first intermediate insulating film which is interposed between the second electrode and the third electrode; and
a second intermediate insulating film which is interposed between the fourth electrode and the fifth electrode.

6. The semiconductor device according to claim 5, wherein
the first intermediate insulating film is thicker than the second insulating film, and
the second intermediate insulating film is thicker than the fourth insulating film.

7. The semiconductor device according to claim 3, wherein
a reference potential is to be applied to the first electrode,
a control potential is to be applied to the second electrode, and
the reference potential or the control potential is to be applied to the third electrode.

8. The semiconductor device according to claim 7, wherein
the reference potential is to be applied to the third electrode.

9. The semiconductor device according to claim 3, wherein
the third electrode includes one or a plurality of first lead-out electrodes led out to an opening side of the second groove across the third insulating film, and
the fifth electrode includes one or a plurality of second lead-out electrodes led out to an opening side of the third groove across the fifth insulating film.

10. The semiconductor device according to claim 9, wherein
the second lead-out electrode faces the first lead-out electrode across the first groove.

11. The semiconductor device according to claim 1, further comprising:
a body region which is formed in a surface layer portion of the main surface;
wherein the second groove penetrates through the body region.

12. The semiconductor device according to claim 11, wherein
the third groove demarcates a mesa portion which is constituted of a part of the semiconductor chip with the first groove, and
the body region is not formed in the mesa portion.

13. The semiconductor device according to claim 11, further comprising:
a source region which is formed in a region along the second groove in a surface layer portion of the body region.

14. The semiconductor device according to claim 1, wherein
the first groove is formed in a band shape in a plan view,
the second groove is formed in a band shape extending in parallel with the first groove in a plan view, and
the third groove is formed in a band shape extending in parallel with the first groove in a plan view.

15. The semiconductor device according to claim 1, further comprising:
a plurality of the second grooves.

16. The semiconductor device according to claim 1, further comprising:
a main surface insulating film which is formed on the main surface and insulates the third groove from outside.

17. A semiconductor device comprising:
a semiconductor chip which has a main surface;
a field trench structure which is formed in the main surface and demarcates an active region and a non-active region in the main surface;
a trench gate structure which is formed in the active region at an interval from the field trench structure and faces the field trench structure; and
a dummy trench structure which is formed in the non-active region at an interval from the field trench structure and faces the trench gate structure across the field trench structure.

18. The semiconductor device according to claim 17, wherein
the field trench structure includes a field trench which is formed in the main surface, a field electrode which is embedded at a bottom wall side of the field trench, and a field insulator which is embedded at an opening side of the field trench.

19. The semiconductor device according to claim 18, wherein
the trench gate structure includes a gate trench which is formed in the main surface, an upper electrode which is embedded at an opening side of the gate trench, and a lower electrode which is embedded at a bottom wall side of the gate trench,
the upper electrode faces the field insulator across a part of the semiconductor chip, and
the lower electrode faces the field electrode across a part of the semiconductor chip.

20. The semiconductor device according to claim 18, wherein
the dummy trench structure includes a dummy trench which is formed in the main surface and a dummy electrode which is embedded in the dummy trench, and
the dummy electrode faces the field electrode and the field insulator across a part of the semiconductor chip.
